(19) United States
(12) Patent Application Publication
(10) Pub. No.: US 2023/0050475 A1
(43) Pub. Date: Feb. 16, 2023

(54) Wide-Bandgap Semiconductor Bipolar Charge-Trapping Non-Volatile Memory with Single Insulating Layer and A Fabrication Method Thereof

(71) Applicant: The Hong Kong University of Science and Technology, Hong Kong (CN)

(72) Inventors: Jing CHEN, Hong Kong (CN); Zheyang ZHENG, Hong Kong (CN); Tao CHEN, Hong Kong (CN); Li ZHANG, Hong Kong (CN)

(21) Appl. No.: 17/816,747

(22) Filed: Aug. 2, 2022

Related U.S. Application Data
(60) Provisional application No. 63/232,661, filed on Aug. 13, 2021.

(51) Int. Cl. H01L 27/118; H01L 29/20; H01L 29/205; H01L 29/423; H01L 29/778; H01L 21/28; H01L 29/66

(52) U.S. Cl. CPC H01L 27/11807; H01L 29/2003; H01L 29/205; H01L 29/4234; H01L 29/7786; H01L 29/40117; H01L 29/66462; H01L 2027/11838

(57) ABSTRACT

Provided herein are a wide-bandgap semiconductor bipolar charge trapping (BCT) non-volatile memory structure with only one single insulating layer and a fabrication method thereof. Monolithically integrated enhancement-mode (E-mode) n-channel and p-channel field effect transistors (n-FETs and p-FETs) for gallium nitride (GaN)-based complementary logic (CL) gates based on the proposed memory structure, together with a fabrication method thereof in a single process run and various logic circuits incorporating one or more of the GaN-based CL gates, are also provided herein.

### CROSS-REFERENCE TO RELATED APPLICATION

This application claims priority from a U.S. provisional patent application No. 63/232,661 filed Aug. 13, 2021, and the disclosure of which is incorporated herein by reference in its entirety.

### TECHNICAL FIELD

The present invention relates to a charge-trapping semiconductor device, particularly, to a wide-bandgap (WBG) semiconductor BCT non-volatile memory device or structure with only one single insulating layer and the fabrication method thereof. The present invention also relates to a method of using the proposed structure in constructing monolithic enhancement-mode n-FETs and p-FETs on a single substrate for various logic circuits.

### BACKGROUND

Charge-trapping-based memory is a representative semiconductor-based non-volatile memory, featuring a gate stack comprising gate electrode, blocking oxide (BO), charge trapping layer (TL), tunnel oxide (TO), and the semiconductor channel [1]-[4]. It is suitable for high-density 3D integration with adequate retention time, thereby widely applied in the flash memory and the solid-state drive. However, it is still challenging to deploy such non-volatile memories in the vicinity of the control processing unit (CPU) with high-speed, high-throughput data exchange, mainly hindered by the still relatively slow programming/erasing (P/E) speed and low endurance. The 1^{st} and 2^{nd} tiers in the memory hierarchy in most of the modern computers are still volatile ones that can be written and read within sub-nanosecond but more than a quadrillion times, e.g., the static/dynamic random-access memory (SRAM and DRAM).

There is a trilemma among high endurance, high speed, and long retention time for the traditional charge-trapping memories. For the retention phase, the TO layer serves as a barrier between TL and semiconductor channel to constrain the stored charges. The large band offset between TO and TL favors the long retention time. For the P/E phases, the TO layer is resistant to charge transferring between TL and the semiconductor channel. Thus, a thin TO layer and high P/E voltage are required for a fast P/E speed, which in turn imposes excessive electrical stress on the TO layer and is unfavorable for high endurance. For these reasons, the state-of-the-art charge-trapping flash memories present a long P/E time ranging from 10 μs to 10 ms and a maximum P/E cycle of 10⁵ for a retention lifetime over 10 years [1-4].

Some approaches have been proposed to address the issues on P/E speed and/or endurance for charge-trapping based memory devices. A semi-floating gate memory has been demonstrated to achieve an ultra-fast P/E time [5]. By deploying a semiconductor junction diode connected to the charge storage layer, the electrical connections of the charge storage layer switched from floating to semi-floating, realizing an ultra-fast P/E time of several nanoseconds. However, due to the narrow bandgap of silicon semiconductor (˜1.1 eV), the retention time needs to be greatly compromised.

A need therefore exists for an improved non-volatile memory structure to realize high P/E speed whilst high endurance and long retention time, which at least diminishes or substantially eliminates the disadvantages and problems described above.

### SUMMARY OF THE INVENTION

The present disclosure proposes a wide-bandgap (WBG) semiconductor bipolar charge trapping (BCT) non-volatile memory with only one single insulation layer. In particular, the proposed WBG semiconductor BCT non-volatile memory structure utilizes semiconductor materials with wide bandgap including, but not limited to, gallium nitride (GaN), to enhance data retention capability and bipolar charge trapping process, thereby increasing the speed of data P/E concurrently with enhanced endurance. Preferably, the proposed WBG semiconductor BCT non-volatile memory structure is fabricated based on GaN-based heterojunctions, or a planar GaN heterojunction-based high-electron-mobility transistor (HEMT). The proposed WBG semiconductor BCT non-volatile memory structure provides sufficient barrier heights within the semiconductor for hole and electron injections and trapping in the absence of TO. Only an external voltage bias is needed at the P/E phases of the proposed structure to reduce barriers in the wide-bandgap semiconductor junctions for electron injection and for hole diffusion, and an appreciable carrier transport occurs with a reduced E-field in the proposed structure since the external bias compensates the built-in potential, which in turn promises a high endurance. By the proposed structure, up to sub-nanosecond level of P/E speed, larger than 10⁸ cycles of P/E operations, and an effective retention time of longer than 10 years can be delivered. The proposed structure can be fabricated on a commercially available GaN-on-Si platform where peripheral write/read circuits are readily available and could be integrated with other existing or emerging GaN-based electronics or optoelectronics [6-7].

Accordingly, a first aspect of the present invention provides a charge-trapping semiconductor device comprising a structure having a lower wide-bandgap semiconductor channel layer and one or more corresponding ohmic contacts, an upper wide-bandgap semiconductor channel layer and one or more corresponding ohmic contacts in the presence of one or more insulating layers arranged over either or both of the upper wide-bandgap semiconductor channel layer and the lower wide-bandgap semiconductor channel layer, one or more charge trapping layers arranged between the upper wide-bandgap semiconductor channel layer/lower wide-bandgap semiconductor channel layer and their respective insulating layer, and one or more control gates in contact with the corresponding insulating layers.

In certain embodiments, the upper wide-bandgap semiconductor channel layer is n-type doped and the lower wide-bandgap semiconductor channel is p-type doped.

In certain embodiments, the upper wide-bandgap semiconductor channel layer is p-type doped and the lower wide-bandgap semiconductor channel is n-type doped.

In certain embodiments, either or both of the upper wide-bandgap semiconductor channel layer and the lower wide-bandgap semiconductor layer is/are undoped.

In certain embodiments, at least one of the charge trapping layers is arranged over the upper wide-bandgap semiconductor channel layer; one of the insulating layers is arranged over the charge trapping layer; and one of the control gates is arranged over the insulating layer, forming a top gate structure.

In certain embodiments, at least one of the charge trapping layers is arranged under the lower wide-bandgap semiconductor channel layer; one of the insulating layers is arranged under the charge trapping layer; and one of the control gates is arranged under the insulating layer, forming a bottom gate or buried gate structure.

In other embodiments, an upper charge trapping layer is arranged over the upper wide-bandgap semiconductor channel layer; an upper insulating layer is arranged over the charge trapping layer; and the top control gate is arranged under the insulating layer, forming a top gate structure; while a lower charge trapping layer is arranged under a lower wide-bandgap semiconductor channel layer, a lower insulating layer is arranged under the lower charge trapping layer, and the bottom control gate is arranged under the insulating layer, forming a bottom or buried gate structure.

In certain embodiments, a barrier layer is arranged between the lower wide-bandgap semiconductor channel and the upper wide-bandgap semiconductor channel, which includes, but not limited to, a semiconductor material with a wider bandgap than that of the lower or upper wide-bandgap semiconductor channel layer, or other semiconductor materials forming a heterojunction structure with the lower or upper wide-bandgap semiconductor channel layer.

In certain embodiments, the p-type doped wide-bandgap semiconductor channel layer is made of a p-type doped wide-bandgap semiconductor including, but not limited to, p-type gallium nitride (GaN), p-type silicon carbide (SiC), p-type aluminium nitride (AlN), p-type gallium oxide (Ga₂O₃), p-type diamond, or a wide-bandgap semiconductor heterojunction structure including, but not limited to, AlGaN/GaN and AlN/GaN structure.

In certain embodiments, the n-type doped wide-bandgap semiconductor channel is made of a n-type doped wide-bandgap semiconductor including, but not limited to, n-type GaN, n-type SiC, n-type AlN, n-type Ga₂O₃, n-type diamond, or a wide-bandgap semiconductor heterojunction structure including, but not limited to, AlGaN/GaN and AlN/GaN structure.

In certain embodiments, the undoped wide-bandgap semiconductor channel is made of an undoped wide-bandgap semiconductor including, but not limited to, undoped gallium nitride (GaN), undoped silicon carbide (SiC), undoped aluminium nitride (AlN), undoped gallium oxide (Ga₂O₃), undoped diamond, or a wide-bandgap semiconductor heterojunction structure including, but not limited to, AlGaN/GaN and AlN/GaN structure.

In certain embodiments, the control gate is made by one or more of metal, metal alloy, metal oxide, metal nitride, and heavily doped semiconductors.

Preferably, the control gate is made of one or more of the following materials: Ni, Ti, Al, Ag, Au, W, Cr, TiN, TiW, ITO, and polysilicon.

In certain embodiments, the insulating layer is made of an oxide, nitride dielectric materials, or semiconductor materials having a wider bandgap than that of the lower or upper wide-bandgap semiconductor channel layer.

Preferably, the insulating layer is made of a blocking oxide (BO) including SiO, AlO, GaO, ZrO, HfO, or HfZrO, or nitride dielectric materials including SiN, SiON, AlON, or GaON.

In certain embodiments, the lower and upper wide-bandgap semiconductor channel layers are made of Group III-nitrides including aluminium nitride (AlN), gallium nitride (GaN), or indium nitride (InN), silicon compounds, or silicon carbide (SiC).

In certain embodiments, the upper or lower wide-bandgap semiconductor channel layers have at least two ohmic contacts disposed at two opposing sides of where the control gate is disposed thereon.

In certain embodiments, the charge trapping layer(s) is/are a modified semiconductor surface of the n-type, p-type, or undoped wide-bandgap semiconductor channel layer that is in direct contact with the insulating layer.

In other embodiments, the charge trapping layer is a separate semiconductor layer with a smaller bandgap than that of the n-type, p-type, or undoped wide-bandgap semiconductor channel layer.

In some other embodiments, the charge trapping layer is a metal layer.

In yet other embodiments, the charge trapping layer is a heavily doped semiconductor layer.

In certain embodiments, the lower and upper wide-bandgap semiconductor channel layers are made of the same material, forming a wide-bandgap semiconductor p-n junction.

In other embodiments, one of the wide-bandgap semiconductor channel layers is made of a heterogeneous semiconductor material or multi-layered structure to form a heterojunction with the other wide-bandgap semiconductor channel layer.

In certain embodiments, the lower or upper wide-bandgap semiconductor channel layer is also a substrate of the present device.

In other embodiments, the lower or upper wide-bandgap semiconductor channel layer has other substrate materials disposed thereunder.

Preferably, at least one ohmic contact of the lower or upper wide-bandgap semiconductor channel layer has an independent electrode.

In certain embodiments, at least one ohmic contact of one of wide-bandgap semiconductor layer is shorted with one of the at least two ohmic contacts of the other wide-bandgap semiconductor channel layer through interconnection metal.

In certain embodiments, at least one ohmic contact is a pair of n-type ohmic contacts disposed on a barrier layer arranged over the lower wide-bandgap semiconductor layer at where the upper wide-bandgap semiconductor channel layer arranged over the barrier layer is selectively removed to expose partially the barrier layer, and on two opposing sides of the remaining upper wide-bandgap semiconductor channel layer at which the control gate is provided thereon.

In certain embodiments, the charge-trapping semiconductor device is a buried p-type channel gallium nitride (GaN) field effect transistor (p-FET) charge-trapping memory device which can be mainly divided into two parts, p-channel part and n-channel part.

In certain embodiments, the p-FET charge-trapping memory device includes a substrate, a buffer layer arranged over the substrate, a n-type wide-bandgap semiconductor channel layer arranged over the buffer layer, the barrier layer arranged over the n-type wide-bandgap semiconductor channel layer, a p-type doped GaN (p-GaN) forming the p-type wide-bandgap semiconductor channel layer arranged over the barrier layer, and a gate structure disposed over a recess of the p-GaN channel layer.

In certain embodiments, on the p-GaN channel layer, a n-type heterojunction channel region is formed by selectively removing part of the p-GaN channel layer from the barrier layer.

In certain embodiments, at least one n-type ohmic contact is formed on the n-type heterojunction channel region.

In certain embodiments, a pair of p-type ohmic contacts being source and drain contacts, respectively, of the p-FET charge trapping memory device is formed on two opposing sides of where the gate structure is to be disposed over the recess of the p-GaN channel.

In certain embodiments, the gate structure includes a charge trapping layer (TL), a dielectric layer serving as the blocking oxide (BO) layer arranged over the TL, and a gate electrode arranged over the BO layer.

In certain embodiments, the substrate is selected from silicon, sapphire, diamond, SiC, AlN, or GaN.

In certain embodiments, the buffer layer is selected from AlN, GaN, InN, or any alloys thereof.

A second aspect of the present invention provides a method of fabricating the charge-trapping semiconductor device according to certain embodiments described herein, where the method includes:

Providing a structure comprising at least a substrate, a buffer layer, a lower wide-bandgap semiconductor layer, a barrier layer, and an upper wide-bandgap semiconductor layer;

removing partially the upper wide-bandgap semiconductor channel layer to expose partially the barrier layer, leaving an active region of the upper wide-bandgap semiconductor channel layer on the barrier layer for subsequently engaging a gate structure;

providing a pair of identical ohmic contacts on two opposing sides of a region of the barrier layer from where the upper wide-bandgap semiconductor channel layer is removed;

providing a pair of ohmic contacts on two opposing sides of the active region of the upper wide-bandgap semiconductor channel layer from where the gate structure is to be engaged;

providing a recess at the active region of the upper wide-bandgap semiconductor channel layer for engaging the gate structure;

providing a charge trapping layer on top of a surface of the recess of the upper wide-bandgap semiconductor layer;

providing an insulating layer over the ohmic contacts, the charge trapping layer and other regions on the upper wide-bandgap semiconductor channel layer and barrier layer than those provided with the ohmic contacts;

providing the gate electrode over the recess of the upper wide-bandgap semiconductor channel layer to cover at least the gate foot region at where the insulating layer is provided over the charge trapping layer in the recess;

selectively removing the insulating layer from those covering the horizontal surface of the ohmic contacts and partially the vertical surface thereof such that the upper wide-bandgap semiconductor channel layer remains insulated by the insulating layer while the contact windows of the corresponding ohmic contacts are opened; and depositing pad metal on the gate electrodes and ohmic contacts to form pad thereon.

In certain embodiments, a silicon wafer is selected as the substrate. Other possible candidates such as sapphire, diamond, SiC, AlN, and GaN can also be selected.

In certain embodiments, the buffer layer is selected from AlN, GaN or InN, or alloys thereof.

In certain embodiments, a GaN channel layer is selected as the lower wide-bandgap semiconductor channel layer.

In certain embodiments, the GaN channel layer being the lower wide-bandgap semiconductor channel layer is unintentionally doped with magnesium.

In certain embodiments, an aluminium gallium nitride (AlGaN) barrier layer is selected as the barrier layer. Other possible barrier layer materials can be selected from AlN, GaN, InN, or any alloys thereof.

In certain embodiments, the barrier layer can be a single layer or a multi-layered structure.

In certain embodiments, the upper wide-bandgap semiconductor channel layer is made of the same material as that of the lower wide-bandgap semiconductor channel layer.

In certain embodiments, the lower wide-bandgap semiconductor channel layer is n-type doped and the upper wide-bandgap semiconductor channel layer is p-type doped.

In certain embodiments, the lower wide-bandgap semiconductor channel layer is p-type doped and the upper wide-bandgap semiconductor channel layer is n-type doped.

In certain embodiments, either or both of the lower wide-bandgap semiconductor channel layer and the upper wide-bandgap semiconductor channel layer is/are undoped.

In certain embodiments, the n-type doped wide-bandgap semiconductor channel layer is made by n-type wide-bandgap semiconductor including, but not limited to, n-type GaN, n-type SiC, n-type AlN, n-type Ga₂O₃, n-type diamond, or a wide-bandgap semiconductor heterojunction structure including, but not limited to, AlGaN/GaN, and AlN/GaN structure.

In certain embodiments, the p-type doped wide-bandgap semiconductor channel layer is made by p-type wide-bandgap semiconductor including, but not limited to, p-type GaN, p-type SiC, p-type AlN, p-type Ga₂O₃, p-type diamond, or a wide-bandgap semiconductor heterojunction structure including, but not limited to, AlGaN/GaN, and AlN/GaN structure.

In certain embodiments, the partial removal of the upper wide-bandgap semiconductor channel layer to partially expose the barrier layer and leave the active region for engaging the gate structure is by dry etching such as plasma dry etching, or digital etching, or a combination thereof.

In certain embodiments, the pair of identical ohmic contacts on the two opposing sides of the region of the barrier layer from where the upper wide-bandgap semiconductor channel layer is removed are made of metal, metal alloy, metal oxide, metal nitride, heavily doped semiconductors through epitaxial growth with chemical vapor deposition, molecular beam epitaxy, sputtering, atomic layer deposition, or evaporation, or alike.

In certain embodiments, the pair of unidentical ohmic contacts on two opposing sides of the active region of the upper wide-bandgap semiconductor channel layer from where the gate structure is to be received are made of metal, metal alloy, metal oxide, metal nitride, heavily doped semiconductors through epitaxial growth with chemical vapor deposition, molecular beam epitaxy, sputtering, atomic layer deposition, or evaporation, or alike.

In certain embodiments, the recess of the upper wide-bandgap semiconductor channel layer is provided through dry etching, digital etching, or a combination thereof.

In certain embodiments, the charge trapping layer is provided through plasma treatment to the upper wide-bandgap semiconductor channel layer, including oxygen plasma treatment, or through epitaxial growth with chemical vapor deposition, molecular beam epitaxy, sputtering, atomic layer deposition, or evaporation, or alike.

In certain embodiments, the insulating layer is provided by formation of a dielectric layer through epitaxial growth with chemical vapor deposition, molecular beam epitaxy, sputtering, atomic layer deposition, or evaporation, or alike.

In certain embodiments, the gate electrode is made of metal, metal alloy, metal oxide, metal nitride, or heavily doped semiconductors, and is provided through epitaxial growth with chemical vapor deposition, molecular beam epitaxy, sputtering, atomic layer deposition, or evaporation, or alike.

In certain embodiments, the selective removal of insulating layer from the upper wide-bandgap semiconductor channel layer for forming contact windows of the corresponding ohmic contacts is by dry etching such as plasma dry etching, or digital etching, or a combination thereof.

In certain embodiments, the contact windows of the corresponding ohmic contacts are probed with pad metal to form pad windows, and the ohmic contacts include both source and drain contacts.

In certain embodiments, the pad metal includes one or more of Ni, Ti, Al, Ag, Au, W, Cr, and any alloys thereof.

A third aspect of the present invention provides monolithically integrated enhancement mode (E-mode) n-channel and p-channel field effect transistors (n-FETs and p-FETs) on a single substrate for a wide-bandgap semiconductor-based complementary logic (CL) gate, and a method of fabricating the same in a single process run, which includes:

providing a substrate with a buffer layer arranged over the substrate, a lower wide-bandgap semiconductor channel layer arranged over the buffer layer, a barrier layer arranged over the lower wide-bandgap semiconductor channel layer, and an upper wide-bandgap semiconductor channel layer arranged over the barrier layer; providing a hard mask over the upper wide-bandgap semiconductor channel layer for masking during a subsequent patterning;

selectively removing unmasked upper wide-bandgap semiconductor layer from a gate region of the n-FETs and a region outside the p-FETs;

removing hard mask from where the upper wide-bandgap semiconductor channel is selectively removed, followed by depositing a surface passivation layer on p-FETs and n-FETs regions;

providing corresponding ohmic contacts on the n-FETs and p-FETs by opening contact windows in corresponding regions on the surface passivation layer, respectively;

removing the surface passivation layer over the gate region of the p-FETs, followed by recessing the upper wide-bandgap semiconductor channel layer to form a recessed p-FET gate region;

subjecting the recessed p-FET gate region to surface treatment, followed by depositing a dielectric layer onto both the n-FETs and p-FETs;

isolating the n-FETs and p-FETs by a multi-energy level ion implantation;

selectively removing the dielectric layer from the corresponding ohmic contacts and gate region of the n-FETs;

providing gate electrodes over the corresponding gate region of the n-FETs and p-FETs, respectively; and

depositing pad metal on the gate electrodes and ohmic contacts to form pad thereon.

In certain embodiments, a silicon wafer is selected as the substrate. Other possible candidates such as sapphire, diamond, SiC, AlN, and GaN can also be selected.

In certain embodiments, the buffer layer is selected from AlN, GaN or InN, or alloys thereof.

In certain embodiments, an aluminium gallium nitride (AlGaN) barrier layer is selected as the barrier layer. Other possible barrier layer materials can be selected from AlN, GaN, InN, or any alloys thereof.

In certain embodiments, a GaN channel layer is selected as the lower wide-bandgap semiconductor channel layer.

In certain embodiments, the lower wide-bandgap semiconductor channel layer is n-type doped and the upper wide-bandgap semiconductor channel layer is p-type doped.

In certain embodiments, the lower wide-bandgap semiconductor channel layer is p-type doped and the upper wide-bandgap semiconductor channel layer is n-type doped.

In certain embodiments, the lower wide-bandgap semiconductor channel layer and/or the upper wide-bandgap semiconductor channel layer is undoped.

In certain embodiments, the n-type wide-bandgap semiconductor channel layer is made of n-type wide-bandgap semiconductor including, but not limited to, n-type GaN, n-type SiC, n-type AlN, n-type Ga₂O₃, n-type diamond, or a wide-bandgap semiconductor heterojunction structure including, but not limited to, AlGaN/GaN, and AlN/GaN structure.

In certain embodiments, the p-type wide-bandgap semiconductor channel layer is made of p-type wide-bandgap semiconductor including, but not limited to, p-type GaN, p-type SiC, p-type AlN, p-type Ga₂O₃, p-type diamond, or a wide-bandgap semiconductor heterojunction structure including, but not limited to, AlGaN/GaN, and AlN/GaN structure.

In certain embodiments, the dielectric layer is made of an oxide, nitride dielectric materials, or semiconductor materials having a wider bandgap than that of the wide-bandgap semiconductor channel layer.

In certain embodiments, the dielectric layer is made of SiO, AlO, GaO, ZrO, HfO, or HfZrO, or nitride dielectric materials including SiN, SiON, AlON, or GaON.

In certain embodiments, the hard mask and the surface passivation layer are both made of silicon oxide.

In certain embodiments, the surface passivation layer is made of SiO, AlO, GaO, ZrO, HfO, or HfZrO, or nitride dielectric materials including SiN, AlN, SiON, AlON, or GaON, or a bilayered or multilayered dielectric material including, but not limited to, AlN/SiN, AlN/SiO, AlN/AlO, AlON/AlN/SiN, AlON/AlN/SiO, or AlON/AlN/AlO.

In certain embodiments, the surface treatment on the recessed p-GaN gate region is implemented by plasma treatment including, but not limited to, oxygen plasma, hydrogen plasma, and nitrogen plasma, or solvent treatment including, but not limited to, hydrochloric acid, hydrosulfuric acid, hydrofluoric acid, piranha solution, tetramethylammonium hydroxide solution, ammonia solution with or without dilution.

In certain embodiments, the multi-energy level ion implantation is selected from fluorine ion implantation.

In certain embodiments, the corresponding gates of the n-FETs to p-FETs have a gate aspect ratio of 1:10.

In certain embodiments, the ohmic contacts of each of the n-FET and p-FET are source and drain contacts.

In certain embodiments, the pad metal includes one or more of Ni, Ti, Al, Ag, Au, W, Cr, and any alloys thereof.

Other aspects of the present invention include an integrated GaN complementary logic (CL) gate prepared by the method described in the third aspect, a single-stage or multi-stage logic circuit incorporating one or more of the integrated GaN CL gates, where the single-stage logic circuit includes, but not limited to, inverters, not-or (NOR) gates, not-and (NAND) gates, and transmission gates; the multi-stage logic circuit includes, but not limited to, latch cell and ring oscillator with up to 15 stages of the complementary logic gates.

This summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Other aspects of the present invention are disclosed as illustrated by the embodiments hereinafter.

### BRIEF DESCRIPTION OF DRAWINGS

The appended drawings, where like reference numerals refer to identical or functionally similar elements, contain figures of certain embodiments to further illustrate and clarify the above and other aspects, advantages and features of the present invention. It will be appreciated that these drawings depict embodiments of the invention and are not intended to limit its scope. The invention will be described and explained with additional specificity and detail through the use of the accompanying drawings in which:

FIG. 1A shows a top view of the charge-trapping semiconductor device on GaN heterojunctions according to certain embodiments of the present invention;

FIG. 1B shows a cross-sectional view (A-A′) of the device shown in FIG. 1A for the p-channel part;

FIG. 1C shows another cross-sectional view (B-B′) of the device shown in FIG. 1A for the n-channel part;

FIG. 2 shows a flowchart depicting a method of fabricating the charge-trapping semiconductor device on GaN heterojunctions according to certain embodiments of the present invention;

FIG. 3 shows a series of cross-sectional views depicting fabrication method according to certain embodiments of the present invention in terms of the cross-sections of the p-channel part and n-channel part, respectively;

FIG. 4A shows quasi-static transfer curves of the charge-trapping semiconductor device according to certain embodiments of the present invention;

FIG. 4B shows pulse mode transfer curves of the charge-trapping semiconductor device, showing two memory states and a memory window of 2.2 V, according to certain embodiments of the present invention;

FIG. 5A shows transfer curves measured for the charge-trapping semiconductor device according to certain embodiments of the present invention after erasing operations with different erasing pulse width (t_{E}) and a fixed erasing voltage (V_{E}) of −10 V; dashed lines encircled curves represent those being effectively erased;

FIG. 5B shows transfer curves measured for the charge-trapping semiconductor device according to certain embodiments of the present invention after programming operations with different programming pulse width (t_{P}) and a fixed programming voltage (V_{P}) of 20 V; dash lines encircled curves represent those being effectively programmed;

FIG. 6A shows transfer curves measured for the charge-trapping semiconductor device according to certain embodiments of the present invention after P/E operations with varied delay time for retention characteristics measurement; two different dashed line circles represent retention performance measurements at a fixed erasing voltage and a fixed programming voltage, respectively;

FIG. 6B shows extracted V_{TH} from the corresponding dashed line encircled retention characteristics measurements in FIG. 6A;

FIG. 7A shows transfer curves measured for the charge-trapping semiconductor device according to certain embodiments of the present invention after P/E cycles for endurance characteristics measurement; two different dashed line circles represent endurance characteristics measurements at a fixed erasing voltage (V_{E}) and a fixed programming voltage (V_{P}), respectively;

FIG. 7B shows extracted V_{TH} from the dashed line encircled endurance characteristics measurements with V_{P}=20 V and V_{E}=—10 V as shown in FIG. 7A;

FIG. 8A shows transfer curves measured for the charge-trapping semiconductor device according to certain embodiments of the present invention after different P/E cycles for endurance characteristics measurement; two different dashed line circles represent endurance characteristic measurements at a fixed erasing voltage (V_{E}) and a fixed programming voltage (V_{P}), respectively;

FIG. 8B shows extracted V_{TH} from the dashed line encircled endurance characteristic measurements with V_{P}=10 V and V_{E}=—10 V as shown in FIG. 8A;

FIG. 9 schematically depicts fabrication method of an integrated GaN complementary logics (CL) inverter according to certain embodiments of the present invention;

FIG. 10A schematically depicts from perspective view of the integrated GaN CL inverter prepared according to the fabrication method depicted in FIG. 9;

FIG. 10B schematically depicts corresponding circuitry diagrams of the integrated GaN CL inverter at two static logic states, where only one of the FETs is turned on at each static state;

FIG. 10C schematically depicts energy band diagrams of the n-FET and p-FET of the integrated GaN CL inverter under different logic inputs and how they yield a greatly suppressed static-state power dissipation; “br” and “ox” refer to the barrier layer and oxide dielectric layer, respectively; “E_{Fn},” and “E_{Fp}” denote the quasi-Fermi levels of electrons and holes, respectively, in a non-equilibrium system;

FIG. 10D shows an SEM image of the integrated GaN CL inverter in grayscale; inactive regions of both the n-FET and p-FET are defined by fluorine ion implantation, a planar isolation technique, to make the present device appear to be a planar structure without an obvious mesa-trench;

FIG. 11A shows gate capacitances of the n-FET and p-FET of the integrated GaN CL inverter according to certain embodiments of the present invention; V_{S}, V_{G} and V_{D} denote voltages applied to the source, gate and drain electrodes of the inverter, respectively;

FIG. 11B shows transfer characteristics of the n-FET and p-FET as in FIG. 11A in a logarithmic scale;

FIG. 11C shows output characteristics (I-V) of the n-FET and p-FET of the integrated GaN CL inverter according to certain embodiments of the present invention;

FIG. 12A shows input-output voltage (Vᵢₙ-Vₒᵤₜ) transfer characteristics of the GaN CL inverter according to certain embodiments of the present invention with different supply voltages (V_{dd});

FIG. 12B shows quasi-static power dissipation of the GaN CL inverter according to certain embodiments of the present invention by sourcing current from the power supply under different Vᵢₙ and V_{dd};

FIG. 12C shows voltage gain of the GaN CL inverter according to certain embodiments of the present invention under different Vᵢₙ and V_{dd};

FIG. 12D shows noise margins (1201) of the GaN CL inverter according to certain embodiments of the present invention under V_{dd} of 5 V; 1201 represent areas of transition window; 1203 represent boundaries of the transition window defined at unity-gain points; inset shows an image of the inverter under testing by a three-dimensional confocal laser microscope;

FIG. 12E shows voltage transfer curves of the GaN CL inverter according to certain embodiments of the present invention under different temperatures ranging from room temperature to 200° C.;

FIG. 12F summarizes the noise margins of the GaN CL inverter according to certain embodiments of the present invention under V_{dd} of 5 V at different temperatures in terms of logic “low” and “high” output voltages (denoted as V_{OL} and V_{OH}, respectively), lower and higher input transition voltages (denoted as V_{IL} and V_{IH}, respectively), and transition threshold (VTH);

FIG. 12G shows waveforms of Vᵢₙ and Vₒᵤₜ of the GaN CL inverter according to certain embodiments of the present invention under continuous switching operation at V_{dd} of 5 V and with varying driving frequencies from 100 kHz to 2 MHz;

FIG. 12H shows transfer characteristics of the GaN CL inverter according to certain embodiments of the present invention in terms of their average V_{IH}, V_{TH} and V_{IL} (n=50); Ave.: average; Dev.: deviation;

FIG. 13A shows a grayscale image by confocal laser microscope of NAND gate prepared according to certain embodiments of the present invention;

FIG. 13B shows a circuitry diagram of the NAND gate as in FIG. 13A;

FIG. 13C shows input-output waveforms of the NAND gate as in FIG. 13A;

FIG. 13D shows a grayscale image by confocal laser microscope of NOR gate prepared according to certain embodiments of the present invention;

FIG. 13E shows a circuitry diagram of the NOR gate as in FIG. 13D;

FIG. 13F shows input-output waveforms of the NOR gate as in FIG. 13D;

FIG. 13G shows a grayscale image by confocal laser microscope of transmission gate prepared according to certain embodiments of the present invention;

FIG. 13H shows a circuitry diagram of the transmission gate as in FIG. 13G;

FIG. 13I shows input-output waveforms of the transmission gate as in FIG. 13G, where the transmission gate is blocked, the output mode is high impedance (high Z);

FIG. 14A shows a circuitry diagram of a latch cell made of two cross-coupled inverters according to certain embodiments of the present invention;

FIG. 14B shows a grayscale image by confocal laser microscope of the latch cell prepared according to the circuitry diagram of FIG. 14A;

FIG. 14C shows input-output waveforms of the latch cell as in FIG. 14B measured under different input voltages and with switch “S” intermittently closed to load the input signal (gray shaded regions);

FIG. 14D shows input-output waveforms of the latch cell as in FIG. 14B measured under long-time bias after loading logic states and opening switch “S”;

FIG. 15A shows a circuitry diagram of an oscillator (OSC) prepared according to certain embodiments of the present invention;

FIG. 15B shows a grayscale image by confocal laser microscope of a 15-stage ring oscillator prepared according to the circuitry diagram of FIG. 15A;

FIG. 15C shows output waveforms at a single oscillation period (T_{osc}) (gray shaded area) of the ring oscillator as in FIG. 15B monitored at an output of the output buffer inverter (with a 5-V V_{dd}) (upper panel) and a corresponding power spectrum (Pₒᵤₜ) with a fundamental frequency at 502 kHz and subsequent harmonic peaks such as at 1.004 MHz (lower panel);

FIG. 15D shows supply voltage dependence of fundamental oscillating frequencies (f_{osc}) of the ring oscillator as in FIG. 15B (upper panel) and its power-delay product of each stage (lower panel);

FIG. 15E shows temperature dependence of the f_{osc} of the ring oscillator shown in FIG. 15D (upper panel) and its power-delay product of each stage (lower panel);

FIG. 15F shows corresponding f_{osc} (upper panel) and oscillating period (T_{osc}) of the ring oscillator as in FIG. 15B with different number of inverter stages (N), where a linear fitting of T_{osc} versus N yields an average propagation delay (τ_{pd}) of 61 ns per stage.

Skilled artisans will appreciate that elements in the figures are illustrated for simplicity and clarity and have not necessarily been depicted to scale.

### DETAILED DESCRIPTION OF THE INVENTION

It will be apparent to those skilled in the art that modifications, including additions and/or substitutions, may be made without departing from the scope and spirit of the invention. Specific details may be omitted so as not to obscure the invention; however, the disclosure is written to enable one skilled in the art to practice the teachings herein without undue experimentation.

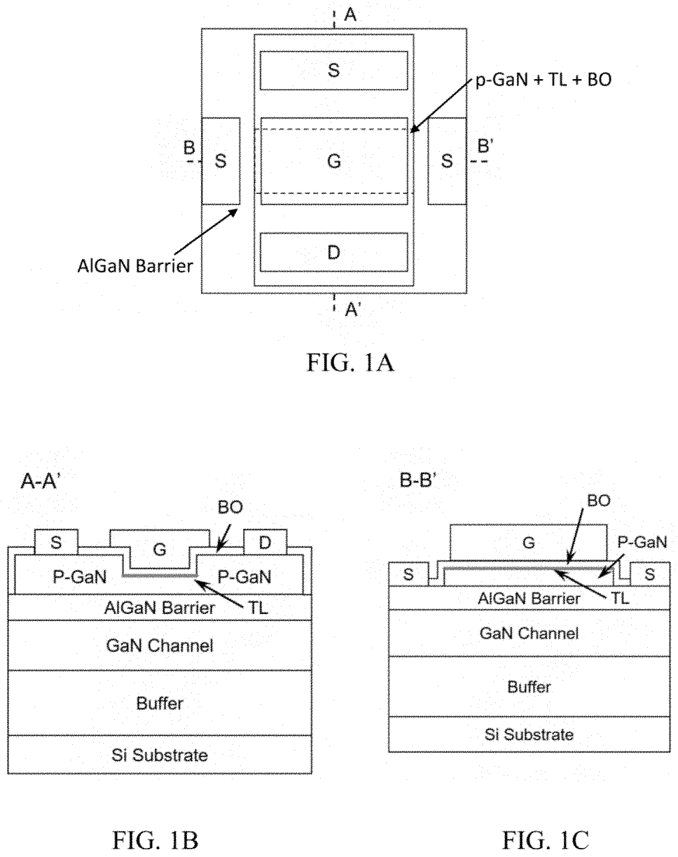

Turning to FIG. 1A, a preferred structure of the present device from the top view thereof is depicted, including at least:

a control gate (G) disposed over a recessed trench (indicated in a rectangular area defined by two parallel dotted lines perpendicular to two dashed lines from top view of FIG. 1A) of an upper wide-bandgap semiconductor, p-type doped GaN (p-GaN), channel layer;

two source (S) and drain (D) contacts disposed on two opposing sides of the control gate and being in contact with the p-GaN channel layer (as in the cross-section of FIG. 1B);

two other identical source contacts (S) disposed on two other opposing sides of the control gate and being in contact with an AlGaN barrier layer (as in the cross-section of FIG. 1C);

except the source and drain contacts, an insulating layer, e.g., blocking oxide (BO) layer, being disposed on the p-GaN channel layer including the recessed trench region under the control gate;

a charge-trapping layer (TL) disposed between the insulating layer and the p-GaN channel layer at a horizontal surface of the recessed trench of the p-GaN channel where the control gate is disposed thereover; and

a lower wide-bandgap semiconductor n-type channel layer (e.g., GaN channel) disposed under the AlGaN barrier layer.

The control gate (G) includes a gate electrode formed by one or more of metal, metal alloy, metal oxide, metal nitride, and heavily doped semiconductors, which include, but not limited to, Ni, Ti, Al, Ag, Au, W, Cr, TiN, TiW, ITO, and polysilicon.

The blocking oxide (BO) forming the insulating layer includes, but not limited to, SiO, AlO, GaO, ZrO, HfO, and HfZrO. Other potential materials for making the insulating layer include nitride dielectric materials or semiconductor materials having a wider bandgap than that of the wide-bandgap semiconductor channel layer such as SiON, AlON, and GaON.

Besides GaN, the upper and lower wide-bandgap semiconductor channel layers can also be made of silicon carbide (SiC), gallium oxide (Ga₂O₃), aluminium nitride (AlN), diamond, or wide-bandgap semiconductor heterojunction structures including, but not limited to, AlGaN/GaN and AlN/GaN structure.

As seen in FIG. 1B which is a cross-sectional view along A-A′ plane from the top view of the structure in FIG. 1A, the upper wide-bandgap semiconductor channel layer (p-GaN) can have at least two ohmic contacts disposed at two sides of the control gate denoted by D and S, respectively.

The charge-trapping layer (TL) can be a modified semiconductor surface of the wide-bandgap semiconductor channel layer that is in direct contact with the insulating layer, or a separate semiconductor layer with a smaller bandgap than that of the wide-bandgap semiconductor channel layer, or a metal layer.

The lower wide-bandgap semiconductor channel layer can be made of the same material as that of the upper wide-bandgap semiconductor channel layer with different doping type to form a p-n junction with the wide-bandgap semiconductor channel, or a heterogeneous semiconductor material or multi-layered materials to form a heterojunction with the wide-bandgap semiconductor channel.

In the case where the lower wide-bandgap semiconductor channel layer is made of the same material as that of the upper wide-bandgap semiconductor channel layer, one preferred embodiment is GaN. Other possible material can be SiC, Group III-nitrides, Ga₂O₃, or diamond.

The doping type of the upper and lower wide-bandgap semiconductor channel layers can be the same or different.

In certain embodiments, the lower wide-bandgap semiconductor channel layer is also a substrate of the present device.

In other embodiments, the lower wide-bandgap semiconductor channel layer has other substrate materials disposed thereunder.

When the lower wide-bandgap semiconductor channel layer has at least one ohmic contact, it can either be an independent electrode, or as seen in FIG. 1C which is a cross-sectional view along B-B′ plane from the top view of the structure in FIG. 1A, or be shorted with one of the other two ohmic contacts through one or more interconnection metals.

In the case where the lower wide-bandgap semiconductor channel layer is not the substrate of the device, one or more of the other substrate materials such as a buffer layer, a nucleation layer, and/or a silicon wafer can be disposed thereunder.

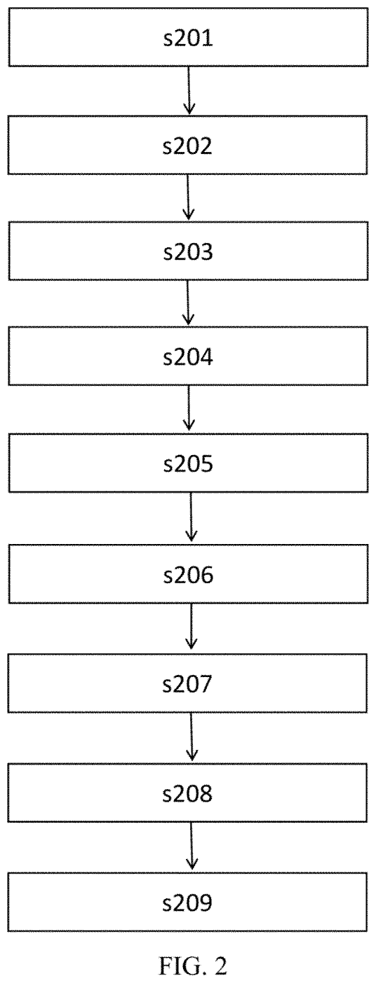

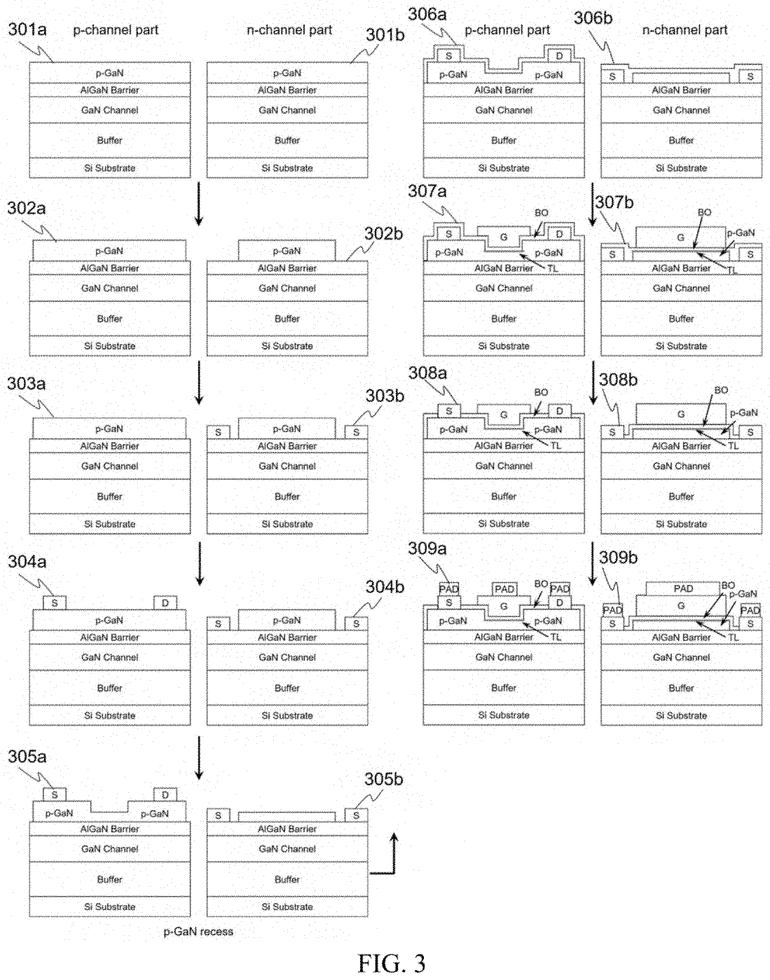

Turning to FIG. 2, a method of fabricating the WBG semiconductor BCT non-volatile memory structure on GaN-based heterojunction according to certain embodiments is depicted as a flow chart. FIG. 3 provides corresponding schematics depicting the geometrical changes in the p-channel and n-channel parts of the present device from their respective cross-sectional views (corresponding to A-A′ and B-B′ planes in FIGS. 1B and 1C, respectively) according to each of the steps depicted in FIG. 2, where the method includes initially providing a buffer layer disposed on a substrate, a GaN channel layer disposed on the buffer layer, an AlGaN barrier layer disposed on the GaN channel layer, and finally a p-GaN layer disposed on the AlGaN barrier layer (s201, 301a, 301b). This initial step is performed if the lower wide-bandgap semiconductor channel layer is not the substrate of the present device. A n-type heterojunction channel region is then formed by selectively etching p-GaN layer therefrom (s202, 302a, 302b). A n-type ohmic contact is then formed on the n-type heterojunction channel (s203, 303b). P-type ohmic source/drain contact is then formed on the p-GaN layer on two opposing sides of a p-GaN gate region to be defined (s204, 304a). The p-GaN layer is then selectively recessed to define the p-GaN gate region (s205, 305a, 305b). After that, a charge trapping layer (TL) and a blocking oxide (BO) layer are sequentially deposited on the p-GaN gate region (s206, 306a, 306b). After the BO layer is formed, a gate contact (e.g., a gate electrode) is further formed on the BO layer at the P-GaN gate region (s207, 307a, 307b). The source and drain contacts are opened by removing the corresponding BO layer therefrom (s208, 308a, 308b), followed by probing pad metal on the source, drain, and gate contacts to form pads thereon (s209, 309a, 309b). Other details of performing each of the steps of the present method will be provided in other embodiments or examples described hereinafter.

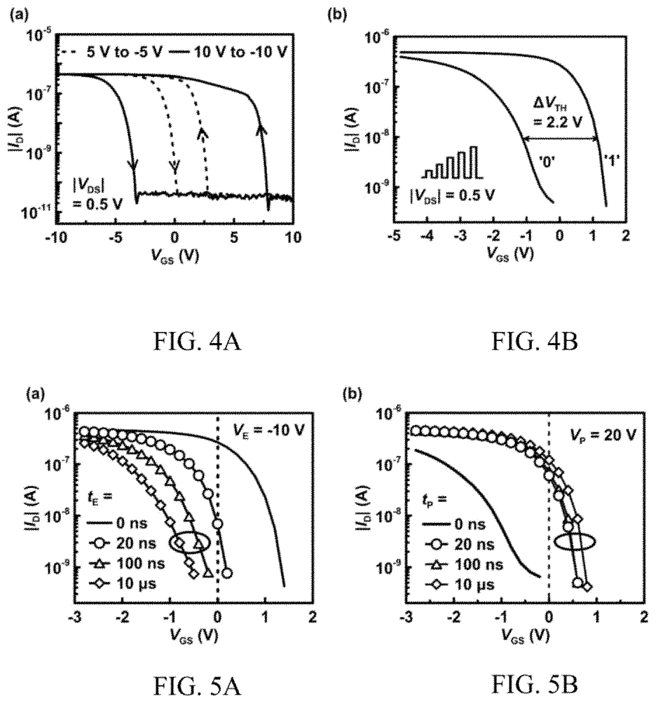

Turning to FIGS. 4A and 4B, a large hysteresis window shows the excellent suitability of the proposed WBG semiconductor BCT non-volatile memory device for memory applications.

Turning to FIGS. 5A and 5B, a −10 V erasing voltage with 100 ns erasing pulse width and a 20 V programming voltage with the programming time as short as 20 ns is sufficient for effective programming and erasing, thereby demonstrating an ultra-fast P/E speed by the proposed device.

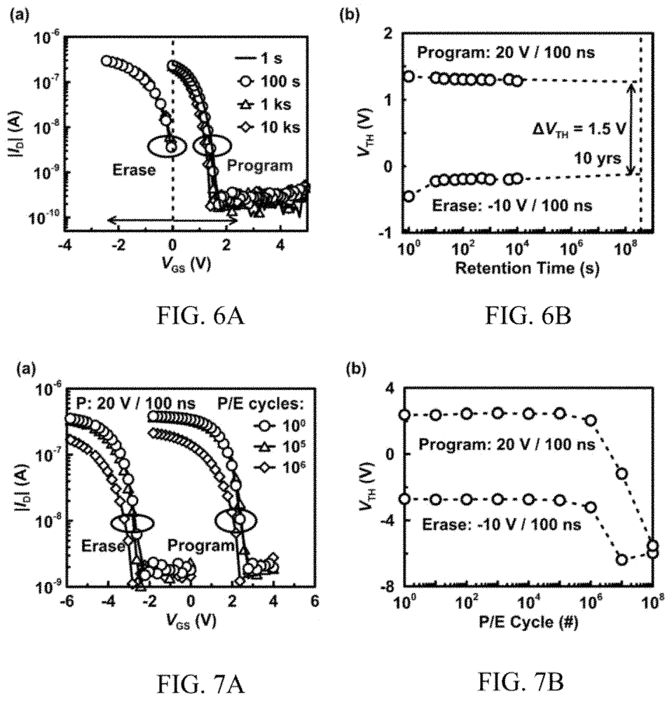

Turning to FIGS. 6A and 6B, it is shown that the proposed device can hold the programmed/erased states after 10⁴ s retention time. A 10-year lifetime is extrapolated based on measured results, and a decent memory window of 1.5 V is retained after the 10-year retention time.

Turning to FIGS. 7A and 7B, it is shown that the proposed device can sustain more than 10⁶ times P/E cycles with no dramatic degradation.

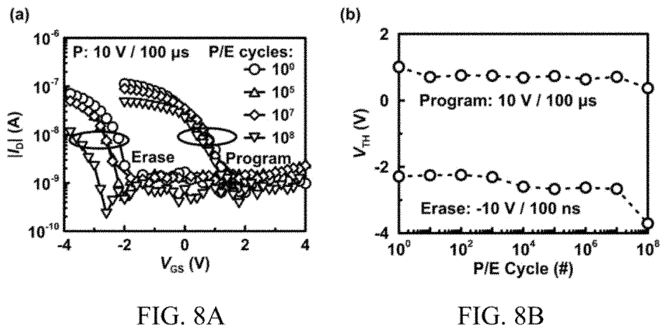

Turning to FIGS. 8A and 8B, the proposed device shows an enhanced endurance performance which can be sustainable more than 10⁸ times P/E cycles.

The following examples will depict how the proposed structure comprising upper and lower wide-bandgap semiconductor channels are applied in different integrated circuits including various complementary logic (CL) gates, and their corresponding fabrication method.

### Examples

(A) Monolithic Integration of Enhancement-Mode (E-Mode) N-Channel and P-Channel GaN Field-Effect Transistors (n-FETs and p-FETs) on Single Substrate for Complementary Logic (CL) Gates

A planar heterojunction-based high-electron-mobility transistor (HEMT) based on gallium nitride (GaN) fabricated on large silicon substrates as a power switch device require peripheral circuits that serve as driving, control, sensing, and protection modules, and therefore monolithic integration is desirable to create on-chip functionalities, enhance robustness, and facilitate the miniaturization of the power conversion system. The planar configuration of GaN HEMTs, i.e., source, gate and drain are located on the top surface, is beneficial to high-density integration, but currently most conventional GaN integrated circuits are mainly based on n-channel devices with electrons as the majority carriers. Also, typical peripheral circuits of GaN power devices are composed of an appreciable number of logic blocks. Complementary metal-oxide-semiconductor (CMOS) topology is dominant among silicon-based logic circuits as it can offer the most energy-efficient scheme for very large-scale integration (VLSI) and mixed-signal ICs. However, there is no suitable integration strategy for incorporating both E-mode n-FETs and p-FETs on a single substrate in the conventional GaN-CMOS circuits.

By using the present fabrication method described herein, integrated CMOS elementary logic gates such as inverters, not-or (NOR) gates, not-and (NAND) gates, and transmission gates, with rail-to-rail operation and ultra-low static power dissipation, and multi-stage logic circuits such as two-stage latch and ring oscillators, are fabricated. Commercially available GaN-on-Si wafers designed for power electronics featuring p-GaN/AlGaN/GaN epitaxial stack can be used as a “substrate” for IC fabrication. An oxygen plasma treatment (OPT) is used to form buried p-channel structured E-mode FETs with characteristics for complementary logic (CL) circuits. For example, the inverters fabricated by the present method exhibit well-placed transition thresholds and a sharp transition region, offering good noise margins and robustness for multi-stage logic gate integration; the two-stage latch and ring oscillators can be fabricated with up to 15-stages.

GaN HEMTs are normally fabricated based on heterojunctions of wurtzite GaN and its alloys such as AlGaN/GaN heterojunction. The non-centrosymmetric wurtzite structure and appreciable electronegativity differences between nitrogen and Group III elements (e.g., Ga, Al, In) induce significant polarization effects in III-nitride compounds, where strains arising from lattice mismatching between different stacking alloy layers induces additional piezoelectric polarizations. High-density polarization charge (˜10¹³ cm⁻²) at the AlGaN/GaN hetero-interface yield a sharp potential well, where two-dimensional electronic gas (2DEG) is formed with very high electron mobility (˜2000 cm²/V s).

Since GaN HEMTs are naturally depletion-mode (D-mode) transistors, to realize E-mode operation, a layer of p-GaN (usually heavily doped) in the gate region on top of the AlGaN layer to deplete the underlying 2DEG.

GaN HEMT's complementary device, such as p-channel GaN FET, is less common because hole mobility in GaN material is rather low (<50 cm²/V s at room temperature, typically ˜15 cm²/V s) compared to the electron mobility, which is inherently rooted in the valence band structure and the intrinsically strong phonon scattering. Despite some appreciable improvements on the designs of p-FET platform to boost the hole mobility or current density, an intrinsic mobility mismatch does not favor GaN as a suitable candidate for advanced CMOS technology geared toward low-power high-speed logic circuits. On the other hand, the desire of monolithically integrating peripheral circuits with GaN power switches that operate at intermediate frequencies offers a compelling yet relaxed opportunity for GaN complementary CL circuits. The typical operating frequencies are in the range of 100 kHz˜10 MHz, technically reachable for GaN CL circuits with acceptable costs. Therefore, the present device starts with the mainstream GaN power platform (p-GaN/AlGaN/GaN-on-Si) instead of other specific epitaxial structures that are designed to maximize the current density of GaN p-FETs.

Venues for n-FETs (at the AlGaN/GaN heterojunction) and p-FETs (in the p-GaN layer) naturally coexist and are inherently de-coupled, as the p-GaN layer and the thin AlGaN barrier layer are designed to deplete the underlying 2DEG n-channel. E-mode n-FETs needed in CL circuits can be realized using the same process for normally-OFF p-GaN gate power HEMTs, with shorter gate-to-drain distance. Intensive epitaxial growth and process optimizations have yielded a high-quality p-GaN layer on such a commercial platform. Hall measurements yield a hole sheet density of ˜1.23×10¹³ cm⁻² and a hole mobility of ˜10.2 cm²/V s at room temperature, which is in the same range as those extracted from other platforms. An essential E-mode operation of p-FETs can be realized by a buried channel structure that maintains reasonable hole current density.

(B) Epitaxial Structure and Fabrication of Integrated GaN CL Inverter

All integrated GaN logic circuits described herein are preferably fabricated on a GaN-on-Si wafer in a single process run. In this example, the n-FETs feature a configuration with a gate-to-source spacing (L_{GS}) of 2 μm, a gate length (L_{G}) of 3.5 μm, a gate-to-drain spacing (L_{GD}) of 2 μm, and a gate width (W_{G}) of 10 μm; the L_{GS}/L_{G}/L_{GD}/W_{G} of the p-FETs were 3/1.5/3/100 μm. The III-nitride epitaxial layer was grown on a p-type low-resistive silicon wafer by metal-organic chemical vapor deposition (MOCVD), consisting of a 4-μm transition/buffer layer, an unintentionally doped GaN channel layer, a 12-nm AlGaN barrier layer, and an 85-nm p-GaN layer with a nominal magnesium doping concentration of ˜3×10¹⁹ cm⁻³. Prior to device fabrication, the sample was subject to wet solution-based cleaning steps, including ultrasonic treatment in acetone and soaking in buffered oxide etchant (BOE) for removal of surface contamination and native oxide. Subsequently, the sample was loaded into a plasma-enhanced chemical vapor deposition (PECVD) chamber for deposition of a ˜70-nm-thick layer of SiO₂ as a hard mask for dry etching of p-GaN.

All pattern definitions were carried out by photolithography. The first patterning was to remove p-GaN outside the regions reserved for p-FETs and the p-GaN gate for n-FETs. The hard mask was opened by reactive ion etching (RIE) using CHF₃/O₂ hybrid gas, followed by p-GaN etching using BCl₃ plasma using an inductively-coupled-plasma reactive ion etching (ICP-RIE) system. The etching depth was controlled by pre-calibrated etching time and examined by atomic force microscopy (AFM). After the dry etching, the hard mask was removed by dipping into BOE. Another 70-nm SiO₂ layer was then deposited to serve as a surface passivation layer. Then, ohmic contacts of n-FETs were formed by opening contact windows on the passivation layer, e-beam evaporating Ti/Al/Ni/Au metal stack (20/150/50/80 nm), lift-off, and 850° C. rapid thermal annealing (RTA) in N₂ atmosphere for 30 sec. Ohmic contacts of p-FETs were formed by a similar manner, while the metal stack was changed to Ni/Au (both are 20 nm thick), and the annealing was performed in an O₂ atmosphere at 550° C. for 10 min. The contact resistance of p-FETs was extracted to be 61 Ω·mm by using the transfer-length method (TLM).

The channel region of p-FET was defined by a recessed trench, which was formed by passivation layer opening by RIE and p-GaN etching by ICP-RIE. A ˜30-nm (out of the 85-nm-total thickness) p-GaN layer was retained as the channel region. To realize E-mode operation, an oxygen plasma treatment (OPT) was performed to the etched p-channel surface in situ in the ICP chamber using low power oxygen plasma. The coil and platen power of ICP plasma were 50 W and 30 W, respectively. The chamber pressure was set at 10 mTorr and the gas flow of O₂ is set at 10 sccm. The treatment time was 1 minute. p-GaN surfaces with and without OPT were characterized by the X-ray photoelectron spectroscopy (XPS).

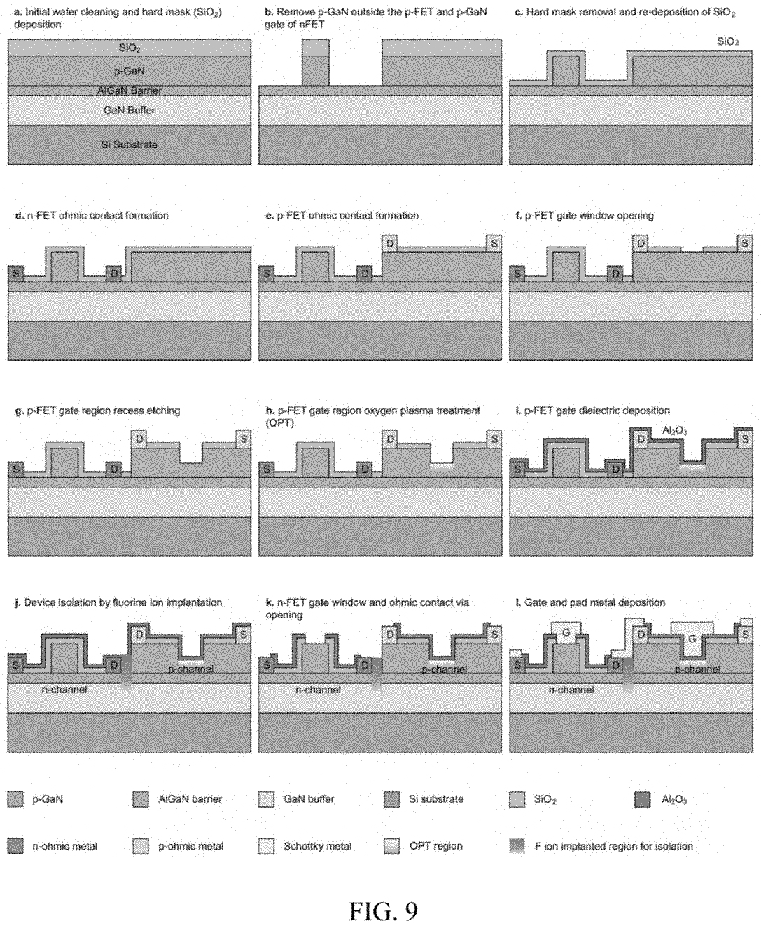

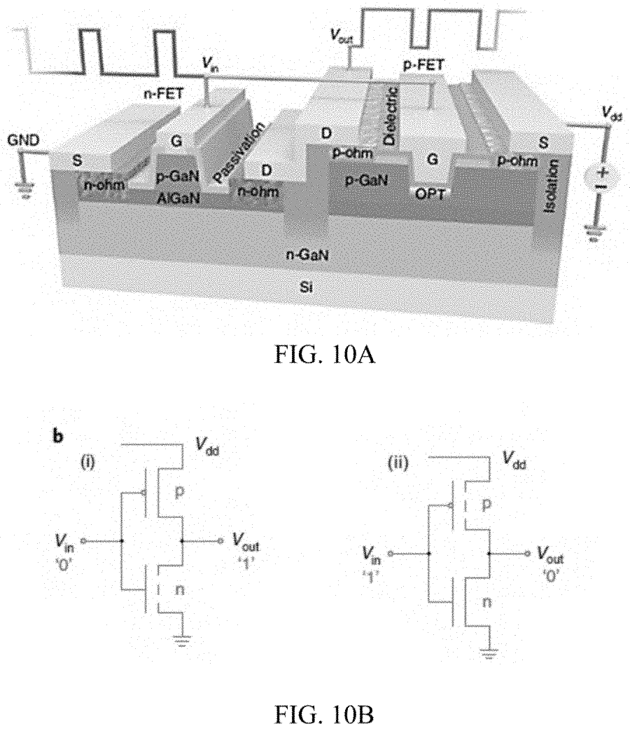

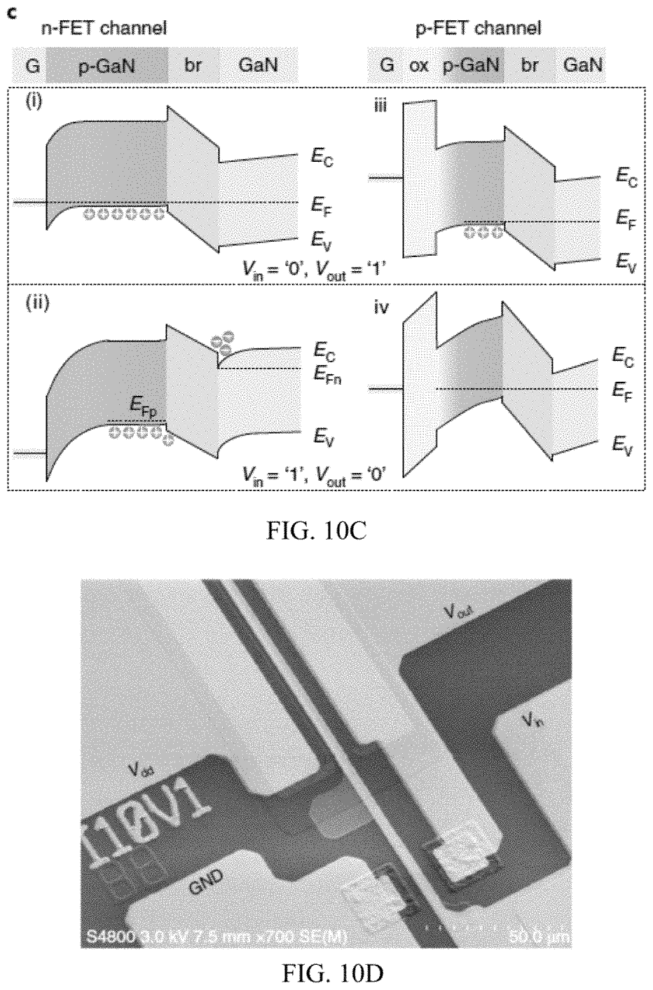

After the OPT, the sample was loaded into an atomic layer deposition (ALD) system for depositing the gate dielectric layer of p-FET. A ˜20-nm Al₂O₃ layer was used as the gate dielectric. Subsequently, device isolation was performed by multi-energy-level (up to 110 keV) fluorine ion implantation. Such a planar isolation technique can get rid of leaky sidewalls in mesa-trench based approaches and effectively suppress the leakage current. In n-FETs, the gate metal was in direct Schottky contact with the p-GaN. Gate electrodes and probing pads of both n-FETs and p-FETs were simultaneously formed by e-beam deposition of Ni/Au and lift-off. A schematic diagram depicting the fabrication process of this example is shown in FIG. 9, and a schematic perspective view and SEM image of the integrated GaN CL inverter prepared according to that fabrication process are depicted in FIGS. 10A and 10D, respectively.

Turning to FIGS. 10B and 10C, the p-GaN layer served as part of the gate stack in the n-FET channel, which elevated the energy band to deplete the underlying 2DEG channel under thermal equilibrium. As a result, the current path from the power supply (V_{dd}) to the ground (GND) was blocked by the n-FET when the input of the inverter was logic ‘0’ (FIG. 10B-(i)). With a positive gate bias, the energy band bended downward, and electrons were induced into the 2DEG channel to conduct current (FIG. 10C-(ii)), whereas in the p-FET channel, the p-GaN under the gate served as the p-channel and was thinned down so that it could be effectively controlled by the gate. An oxygen plasma treatment (OPT) was applied after a moderate recess etching to convert the top portion of the remaining p-GaN into a region free-of-holes as oxygen could either compensate the Mg doping or passivate Mg through the formation of Mg—O complex. Such an OPT process facilitated the depletion of the p-channel under thermal equilibrium (FIG. 10C-(iv)). Thus, the p-FET channel was configured into enhancement-mode (E-mode) and blocked the current path from V_{dd} to GND with a logic ‘1’ input (FIG. 10B-(ii)). Having a negative gate bias with respect to the source (which is tied to V_{dd}), the energy band was pulled upward and a buried p-channel started to form (FIG. 10C-(iii)). In such an ON-state, holes were located in a buried channel, i.e., the p-GaN region that was away from the interface of the dielectric and semiconductor layers where significant disorder/interface scattering occurred. The buried p-channel was of higher crystal quality than the interface region and suffered less adverse effects from the interface where the recess-etching induced damages were concentrated. Reasonable hole current density was thereby achieved with an E-mode operation, enabling the inverter's output to reach the rails of V_{dd} and GND at two logic states, respectively.

(C) Quasi-Static Device Characterization of Discrete n-FET and p-FET Channels

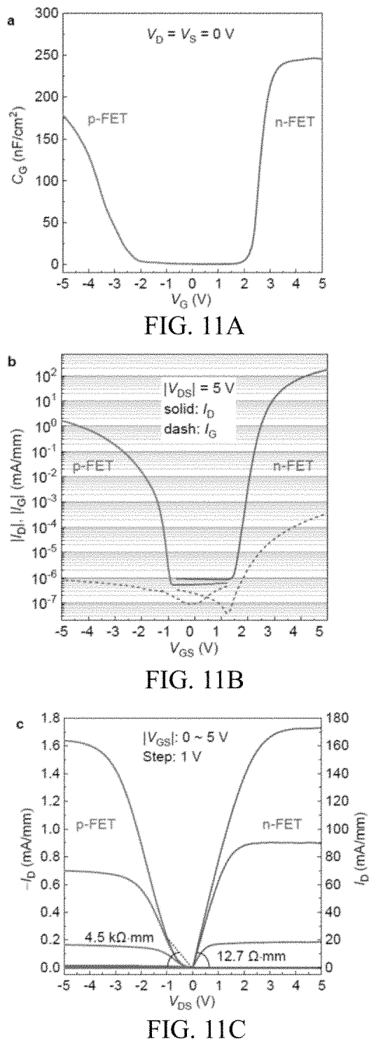

Turning to FIG. 11A, it shows the difference in gate capacitance-gate voltage (C_{G}-V_{G}) characteristics, revealing different device operating principles of the n-FET and p-FET channels. For the n-FET channel, the drain current (I_{D}) was regulated through modulating the electron density in the 2DEG channel. As all carriers were confined within a 2D sheet, they couple with charges in the gate metal through a parallel-plate capacitor and thus the C-V curve of the n-FET channel roughly featured a plateau when the device was turned on. For the buried p-FET channel, within the operating gate voltage range (e.g., 0˜5 V), its I_{D} was modulated by controlling the thickness of the non-depleted p-GaN layer (i.e., the channel). The variable depletion boundary thus resulted in a V_{G}-dependent C_{G}.

Turning to FIG. 11B, the logarithmic-scaled transfer curves show that both n-FET and p-FET channels were true E-mode with nearly symmetric threshold voltages, greatly suppressed gate current and OFF-state drain leakage. Both channels exhibited a high ON/OFF ratio, very small leakage current, and suppressed gate current, owing to the MOS gate stack in the p-FET and the Schottky-type p-GaN/AlGaN/GaN gate stack in the n-FET, thereby yielding high quasi-static/static input impedances of GaN complementary logic blocks that assured the rail-to-rail operation in multi-stage logic circuits, whereas the ultra-low OFF-state leakage assured low static power dissipation at both logic states.

Turning to FIG. 11C, the output current-voltage (I-V) characteristics of the n/p-FET channels indicates a significant mismatch between their current densities due to their intrinsic mismatch between their electron and hole mobilities in the GaN material, and therefore the gate width ratio of the n-FET and p-FET need to be carefully configured to tackle this mismatch. Preferably, the gate width ratio of the n-FET to p-FET is 1:10 in the present invention.

Different from conventional silicon-based CMOS circuits where both p-FETs and n-FETs feature ‘metal-oxide-semiconductor (MOS)’ gate stacks, only the p-FETs have a ‘MOS’ structure whereas the n-FETs are basically heterojunction field-effect transistors (HFETs) according to certain embodiments of the present invention. Therefore, a more appropriate interpretation of the circuits in the present inverter should be ‘complementary logic (CL) circuits’ with ‘CMOS-like’ behaviours, instead of ‘CMOS’. However, it should be noted that there is an additional p-GaN layer on the AlGaN/GaN heterostructure in the gate stack of the E-mode n-FETs in the present invention. As a result, the gate I-V characteristics are significantly different from that of the conventional HFETs, resulting in a more MOSFET-like n-FET. The n-FETs in the present invention feature p-GaN gate stack that can be modelled as a series connection of a p-i-n junction (i.e., the p-GaN/AlGaN/GaN junction) and a gate-metal/p-GaN Schottky junction. The Schottky junction is reverse biased at a positive forward gate bias, resulting in a suppressed gate leakage, a gate forward breakdown voltage of larger than 10 V and an enlarged gate voltage swing, all of which are essential for the operation of GaN complementary IC with a standard 5-V supply voltage.

(D) Characterization of GaN CL Inverters

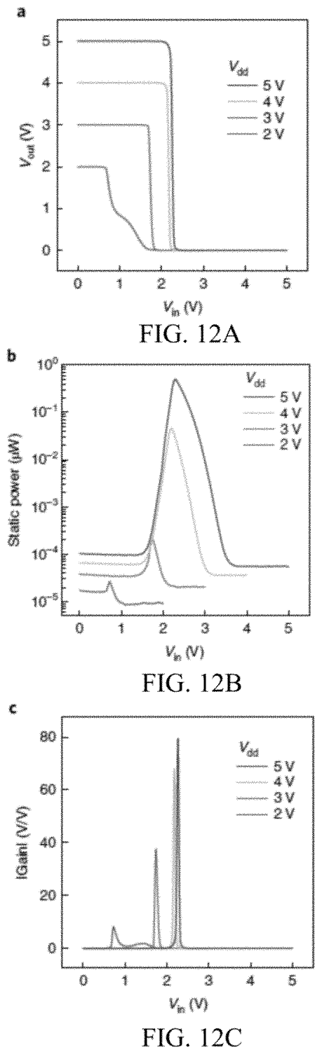

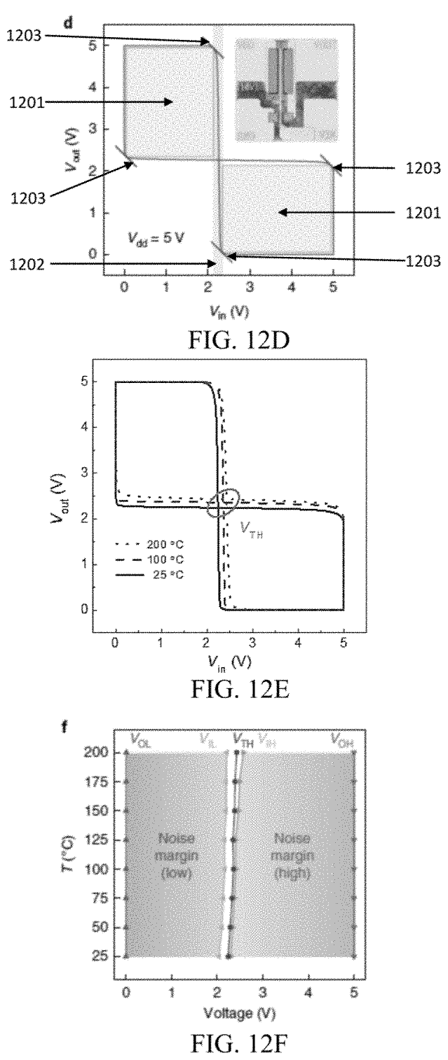

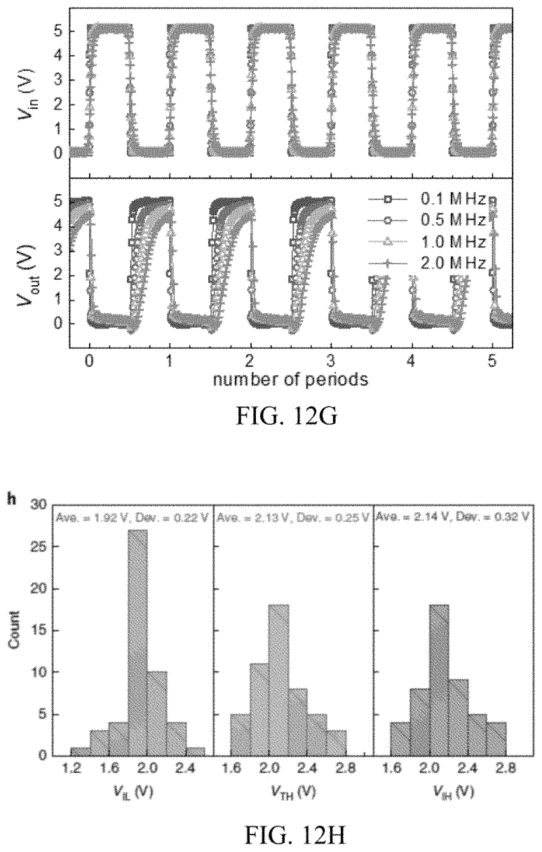

Turning to FIG. 12A, under different supply voltages (V_{dd}), the logic ‘1’ output voltage levels were always equal to the V_{dd}, whereas the logic ‘0’ outputs were always 0 V, i.e., the output of the inverter swung from the rail of V_{dd} to the rail of GND (rail-to-rail), suggesting that rail-to-rail operations were realized. The transition thresholds (V_{TH}), usually defined at Vᵢₙ=Vₒᵤₜ, was located at half of V_{dd} because of the symmetric threshold voltage of the n-FET and p-FET. When the V_{dd} was only 2 V, the GaN CL inverter exhibited a ternary-state behavior, as both n-FET and p-FET were both at the OFF state when Vᵢₙ was around 1 V.

Turning to FIG. 12B, it is shown that power dissipation of the GaN CL inverter occurred during the transition states, but when both n-FETs and p-FETs exhibited stringent E-mode operation and high ON/OFF current ratio (˜10⁷), the power dissipation at both static states (with Vᵢₙ=0 V or V_{dd}) was substantially suppressed by up to 3 orders of magnitude (depending on the V_{dd}) compared to the transition states. This static power dissipation characteristic of the present GaN CL inverter is equivalent to the most important trait of CMOS circuits, i.e., low static-state power dissipation, which outperforms other conventional logic circuit schemes, such as resistor-transistor logic (RTL) or directly-coupled-FET logic (DCFL) structure, in terms of energy efficiency. With an increasing V_{dd}, the transition window becomes narrower, whereas the voltage gain is boosted, where a maximum peak gain of 80V/V was recorded at a 5-V V_{dd} (FIG. 12C).

In GaN power electronics, a 5-V voltage supply is commonly used for logic control sub-circuits. The present inverter is also suitable to be operated with such a 5-V V_{dd}. FIG. 12D shows the noise margin of the present inverter analyzed by cross-coupled inverter voltage transfer relation, where the noise margin of logic ‘low’ (V_{IL}-V_{OL}) was 2.1 V, whereas that of logic ‘high’ (V_{OH}-V_{IH}) was 2.6 V, suggesting that both noise margins were sufficiently large, such that the present inverter is shown to possess high immunity to miscellaneous noises, such as electromagnetic interferences produced by high-frequency power switches.

Turning to FIG. 12E, voltage transfer of the present GaN CL inverter measured under elevating temperatures from room temperature up to 200° C. is shown, from which the characteristic transition voltages are extracted and summarized in FIG. 12F. Despite a slight expansion of transition window and deviations of V_{TH} at high temperatures, superior properties of the GaN CL inverter, such as the rail-to-rail operation, wide noise margins, and the sharp logic state transition, were well preserved. At higher temperatures up to 350° C. (not shown in FIG. 12E), decent noise margins (˜1.83 V) and voltage gains (˜18.1 V/V) are still available, although the output swing experienced a slight compression. In comparison, due to a relatively narrower bandgap in Si (˜1.1 eV), operating temperatures of conventional bulk silicon CMOS circuits are usually limited to 125° C., or 175° C. in some special applications, because Si MOSFETs cannot be effectively turned off and thermally-induced junction leakage current can easily lead to latch-up and malfunction. The silicon-on-insulator (SOI) and silicon carbide (SiC) based CMOS circuits have been developed for operating at higher temperatures. SOI CMOS circuits are free of the latch-up issue and exhibit suppressed bulk leakage current, and thereby can operate at higher temperatures up to 300° C. Owing to the wider bandgap of 3.26 eV in SiC, SiC CMOS have further advanced operating temperature to 400° C. and beyond. On the other hand, GaN possesses a wider bandgap of ˜3.4 eV and provides a favorable platform to develop device and circuits for applications at high temperatures. Furthermore, the heterojunction based epitaxial structures employed in the present invention are naturally free of latch-up process owing to the absence of parasitic thyristor structure. The present GaN CL inverter described herein has demonstrated substantial high-temperature ruggedness, unveiling their promising potential to be deployed in harsh environments.

Turning to FIG. 12G, waveforms of the present inverter under continuous switching operations with varying driving frequencies up to 2 MHz were measured, where the rising time thereof was limited by the p-FET. However, the p-FET in this example had not yet reached the intrinsic limitation of mobility. With further optimization on the channel recess etching and oxidation process, it is expected that the current density of p-FETs will increase and the operating frequency will be consequently boosted by several MHz with the same device dimensions. Moreover, the gate length of p-FET in this example was 1.5 μm due to the limitation of photolithography used. The speed of p-FETs could be profoundly promoted to multi-MHz by reasonable device scaling which simultaneously reduces the channel resistance and gate capacitance. By using 8-inch fabrication lines to produce GaN power HEMT devices, sub-micron lithography can scale the gate length (L_{G}) down to 180˜250 nm. Taking the buried p-channel structure, the voltage supply level, and the short channel effect into consideration, an L_{G} of 250 nm could be adopted to deliver multi-MHz operation in the present GaN CL circuits.

Turning to FIG. 12H, the transfer characteristics of 50 inverters each having a surface area of 2×2 cm² were characterized in terms of their average boundary input voltages (V_{IH}, VII) and transition thresholds (V_{TH}) The tight distribution of V_{IL}, related to the turn-on process of the n-FET, indicates a good uniformity among the fabricated n-FETs. As the p-FETs in the present invention are fabricated by dry etching, the fluctuation in etching depth probably leads to slightly coarser distributions of V_{TH} and V_{IH}. Nevertheless, all inverters described herein are shown to be functional with sufficient noise margins, and the uniformity is expected to be significantly improved during industrial-scale mass production.

(E) Application in Single-Stage GaN Monolithically Integrated CL Gates

Besides being used in an integrated GaN CL inverter, the present device structure is also suitable for forming other elementary CL gates that are essential building blocks of logic circuits.

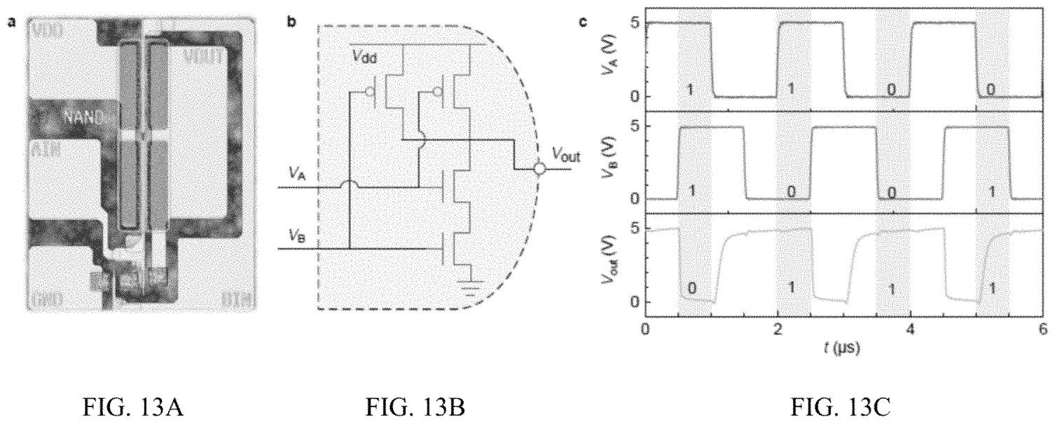

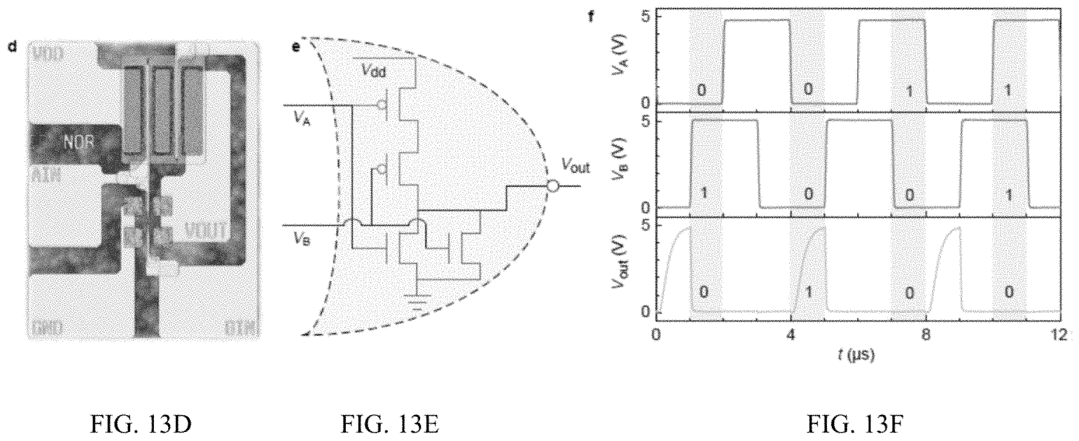

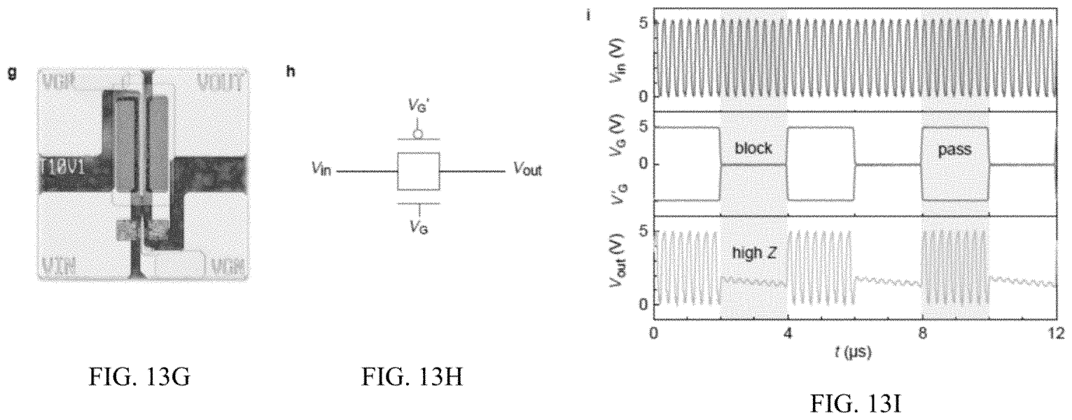

Turning to FIGS. 13A-13I, grayscale images taken by confocal laser microscope of a NAND gate (FIG. 13A), NOR gate (FIG. 13D), and a transmission gate (FIG. 13G), together with their respective circuitry diagrams (FIGS. 13B, 13E, and 13H, respectively) and operating waveforms (FIGS. 13C, 13F and 13I, respectively), are provided, where corresponding logic states are labeled. In this example, both the NAND and the NOR gates demonstrated correct logic operations following their truth tables and delivered rail-to-rail outputs with sub-MHz operating frequencies. The two input signals fed to the NAND gate were both 0.5 MHz with a 90° phase shift, which drove the output signal to toggle at a frequency of 1 MHz equivalently. The NOR gate, however, exhibited a slower switching speed as the two p-FETs were connected in series. Thus, it was characterized with input signals of 0.25 MHz. The device ratio could be further adjusted in different logic gates to yield optimal performance. The transmission gate with complementary n-FET and p-FET in parallel allowed signal to pass without truncation at the ON state and effectively blocks the signal at the OFF state as both the n-FETs and p-FETs could be completely turned off with a V_{Gs} of 0 V.

(F) Multi-stage Logic Circuits—Latch and Ring Oscillators

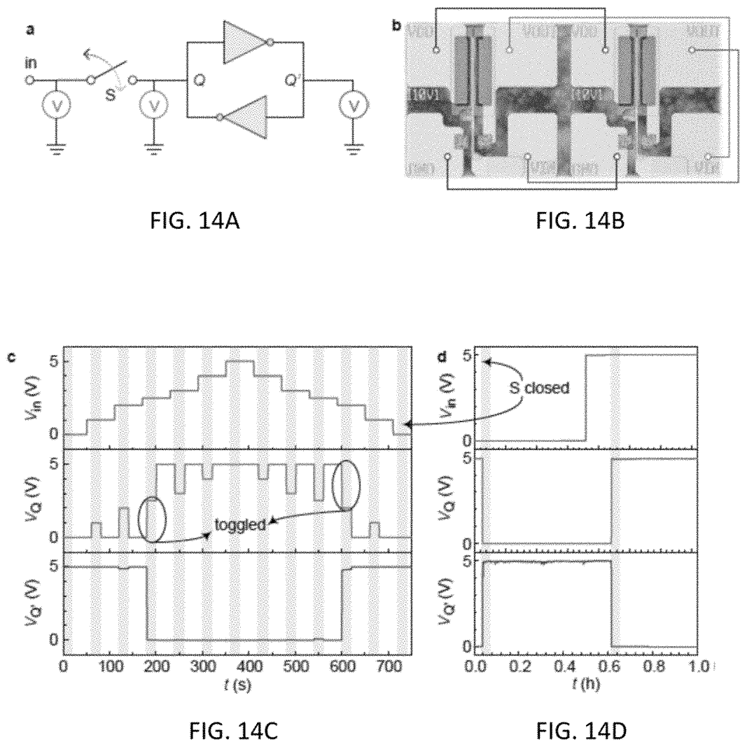

Turning to FIGS. 14A and 14B, to manifest the feasibility of applying the present device in multi-stage logic circuits, a latch cell made of two cross-coupled GaN CL inverters as described herein is provided, where one bit of information could be stored in the latch cell as demonstrated in this example. Different input voltages were loaded to the node Q of the latch cell by intermittently closing the switch ‘S’. With a 5-V V_{dd}, the latch cell maintained the logic state even when an input voltage deviating from static states by 2 V was loaded, owing to the high noise margin in the inverters (FIG. 14C). As shown in FIG. 14D, the logic state could be quickly toggled by external pulses but maintained for a very long time. The capability of storing data enables the implementation of memory units (e.g., the static random-access memory, SRAM) and sequential logic circuits. The results from this example suggests that the present invention is suitable for constructing finite state machines or microprocessors using III-nitrides such as GaN.

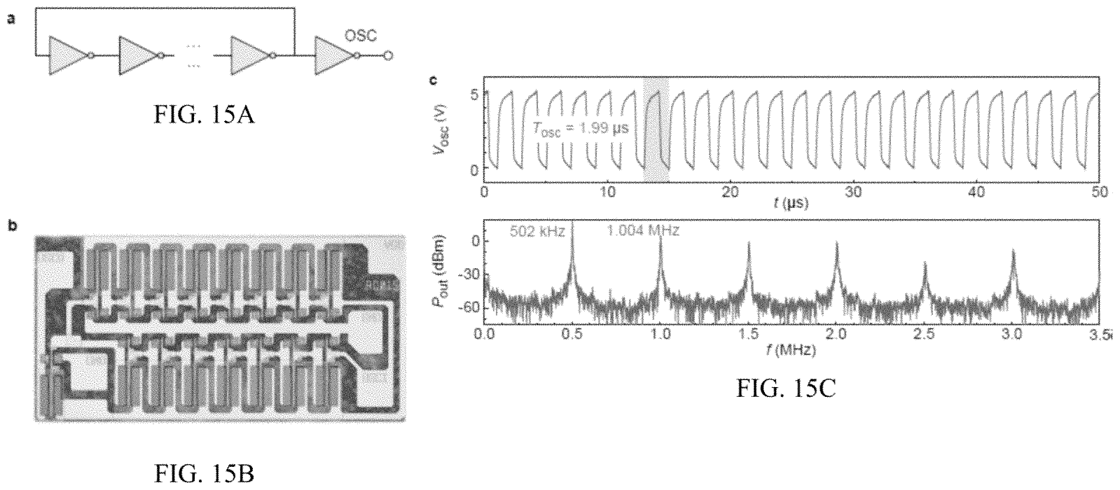

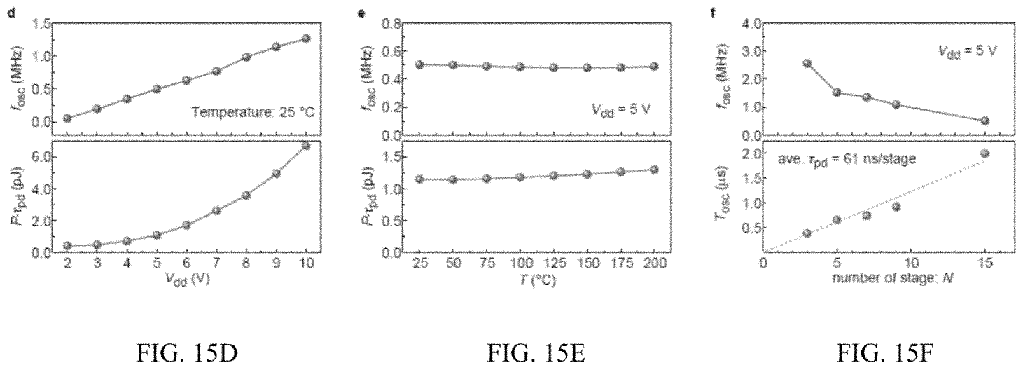

Turning to FIGS. 15A and 15B, a second example of multi-stage logic circuits, ring oscillator, is provided, where it featured 15-stage of inverters cascading into a ring and an additional inverter arranged out of the ring serving as an output buffer of the internal oscillating node. FIG. 15C shows oscillating waveforms (upper panel) and the corresponding power spectrum (lower panel) of the ring oscillator, exhibiting an oscillating period of 1.99 μs and a fundamental frequency of 502 kHz, respectively. FIG. 15D shows the dependence on the supply voltage (V_{dd}) of the fundamental frequency and power-delay product per stage of the ring oscillator. By increasing V_{dd} to this kind of CL gates, the transmission speed of the circuit is boosted with a compromise on dynamic power consumption, which is different from conventional DCFL circuits where increasing V_{dd} does not necessarily lead to a higher speed. FIG. 15E further shows the temperature dependence of the ring oscillator at up to 200° C., where the ring oscillator exhibited a stable oscillating frequency and power-delay product across a wide temperature range, owing to the satisfactory thermal stability of the present inverters. More ring oscillators consisting of different number of inverters are also fabricated and characterized, as shown in FIG. 15F. In FIG. 15F, an average delay of 61 ns per stage can be extracted with a linear fitting. There is still great room for boosting the speed by employing the present fabrication method and interface optimization, reducing the propagation delay to sub-nanosecond to meet the requirements for power electronics switching at MHz frequencies. Successful implementation of the present GaN CL inverters in constructing a CMOS ring oscillator suggests practical applications of the present invention in fabricating complementary logic ICs based on GaN.

From the examples described herein, the single-stage logic inverters and multi-stage logic circuits based on the proposed structure of the present invention exhibit rail-to-rail operation, substantially suppressed static power dissipation, well-placed transition threshold, narrow transition windows with a high voltage gain and good noise margins, and good thermal stability, suggesting that the present invention is suitable for application in harsh environments. The monolithically integrated energy-efficient peripheral circuits based on the proposed GaN CL inverter structure capable of driving, controlling and protecting GaN devices are suitable for high-frequency/high-power-density applications or in harsh environments.

Although the invention has been described in terms of certain embodiments, other embodiments apparent to those of ordinary skill in the art are also within the scope of this invention. Accordingly, the scope of the invention is intended to be defined only by the claims which follow.

### REFERENCES

The following references are cited herein, which are incorporated by reference:
[1] C. H. Lee, K. I. Choi, M. K. Cho, Y. H. Song, K. C. Park, and K. Kim, “A novel SONOS structure of SiO₂/SiN/Al₂O₃ with TaN metal gate for multi-giga bit flash memories,” in 2003 IEEE International Electron Devices Meeting (IEDM), 2003, p. 26.5.1-26.5.4, doi: 10.1109/IEDM.2003.1269356.
[2] H. T. Lue, S. Y. Wang, E. K. Lai, Y. H. Shih, S. C. Lai, L. W. Yang, K. C. Chen, J. Ku, K. Y. Hsieh, R. Liu, and C. Y. Lu, “BE-SONOS: A bandgap engineered SONOS with excellent performance and reliability,” in 2005 IEEE International Electron Devices Meeting (IEDM), 2005, p. 547-550, doi: 10.1109/IEDM.2005.1609404.
[3] M. Ishiduki, Y. Fukuzumi, R. Katsumata, M. Kito, M. Kido, H. Tanaka, Y. Komori, Y. Nagata, T. Fujiwara, T. Maeda, Y. Mikajiri, S. Oota, M. Honda, Y. Iwata, R. Kirisawa, H. Aochi and A. Nitayama, “Optimal Device Structure for Pipe-shaped BiCS Flash Memory for Ultra High Density Storage Device with Excellent Performance and Reliability,” in 2009 IEEE International Electron Devices Meeting (IEDM), 2009, p. 27.3.1-27.3.4, doi: 10.1109/IEDM.2009.5424261.
[4] S. Tsuda, Y. Kawashima, K. Sonoda, A. Yoshitomi, T. Mihara, S. Narumi, M. Inoue, S. Muranaka, T. Maruyama, T. Yamashita, Y. Yamaguchi and D. Hisamoto, “First Demonstration of FinFET Split-Gate MONOS for High-Speed and Highly-Reliable Embedded Flash in 16/14 nm-node and beyond,” in 2016 IEEE International Electron Devices Meeting (IEDM), 2016, p. 11.1.1-11.1.4, doi: 10.1109/IEDM.2016.7838393.
[5] P. Wang, X. Lin, L. Liu, Q. Sun, P. Zhou, X. Liu, W. Liu, Y. Gong, D. W. Zhang, “A Semi-Floating Gate Transistor for Low-Voltage Ultrafast Memory and Sensing Operation,” Science, vol. 334, no. 6146, p. 640-643, August 2013, doi: 10.1126/science.1240961.
[6] Z. Zheng, L. Zhang, W. Song, S. Feng, H. Xu, J. Sun, S. Yang, T. Chen, J. Wei, and K. J. Chen, “Gallium nitride-based complementary logic integrated circuits,” Nat. Electron., July 2021, doi: 10.1038/s41928-021-00611-y.
[7] Z. Zheng, W. Song, L. Zhang, S. Yang, J. Wei, K. J. Chen, “High ION and ION/IOFF ratio enhancement-mode buried p-channel GaN MOSFETs on p-GaN gate power HEMT platform,” IEEE Electron Device Lett., vol. 41, no. 1, January 2020, p. 26-29, doi: 10.1109/LED.2019.2954035.

What is claimed is:

1. A charge-trapping semiconductor device comprising a structure having a lower wide-bandgap semiconductor channel layer and one or more corresponding ohmic contacts, an upper wide-bandgap semiconductor channel layer and one or more corresponding ohmic contacts in the presence of one or more insulating layers arranged over either or both of the upper wide-bandgap semiconductor channel layer and the lower semiconductor channel layer, one or more charge trapping layers arranged between the upper and/or lower wide-bandgap semiconductor channel layers and the one or more insulating layers, and one or more control gate(s) in contact with the corresponding insulating layers.

2. The device of claim 1, wherein the upper wide-bandgap semiconductor channel layer is n-type doped or p-type doped, or undoped; the lower wide-bandgap semiconductor channel layer is p-type doped or n-type doped, or undoped; the corresponding ohmic contacts of the upper wide-bandgap semiconductor channel are p-type ohmic contacts or n-type ohmic contacts; and the corresponding ohmic contacts of the lower wide-bandgap semiconductor channel are a p-type ohmic contacts or n-type ohmic contacts.

3. The device of claim 1, wherein at least one of the charge trapping layers is arranged over the upper wide-bandgap semiconductor channel layer; one of the insulating layers is arranged over the charge trapping layer; and one of the control gates is arranged over the insulating layer, forming a top gate structure.

4. The device of claim 1, wherein an upper charge trapping layer is arranged over the upper wide-bandgap semiconductor channel layer; an upper insulating layer is arranged over the charge trapping layer; a top control gate is arranged over the insulating layer; a lower charge trapping layer is arranged under the lower wide-bandgap semiconductor channel layer; a lower insulating layer is arranged under the charge trapping layer; and a bottom gate is arranged under the lower insulating layer, forming a double gate or dual gate structure.

5. The device of claim 1, wherein the one or more insulating layers is/are made of a blocking oxide selected from SiO, AlO, GaO, ZrO, HfO, or HfZrO, or nitride dielectric materials selected from SiN, SiON, AlON, or GaON.

6. The device of claim 1, wherein the one or more charge trapping layers is/are selected from a modified semiconductor surface of any of the upper or lower wide-bandgap semiconductor channel layer that is in direct contact with the insulating layer, a separate layer from any of the upper or lower wide-bandgap semiconductor channel layer, a heavily doped semiconductor layer, or a metal layer.

7. The device of claim 1, further comprising a barrier layer disposed under the upper wide-bandgap semiconductor channel layer, wherein the barrier layer is a semiconductor material with a wider bandgap than that of the upper or lower wide-bandgap semiconductor channel layer, wherein said semiconductor material comprises AlN, AlGaN, or other semiconductor materials forming a heterojunction structure with the upper or lower wide-bandgap semiconductor channel layer.

8. The device of claim 2, wherein the p-type doped upper or lower wide-bandgap semiconductor channel is selected from p-type GaN, p-type SiC, p-type AlN, p-type Ga₂O₃, p-type diamond, or a wide-bandgap semiconductor heterojunction selected from a AlGaN/GaN, AlN/AlGaN/GaN, AlGaN/AlN/GaN, AlN/AlGaN/AlN/GaN, or AlN/GaN structure; the n-type doped upper or lower wide-bandgap semiconductor channel is selected from n-type GaN, n-type SiC, n-type AlN, n-type Ga₂O₃, n-type diamond, or a wide-bandgap semiconductor heterojunction structure selected from a AlGaN/GaN, AlN/AlGaN/GaN, AlGaN/AlN/GaN, AlN/AlGaN/AlN/GaN, or AlN/GaN structure.

9. The device of claim 1, further comprising a buffer layer and a substrate, when the lower wide-bandgap semiconductor channel is not a substrate, wherein the substrate is selected from silicon, sapphire, diamond, SiC, AlN, or GaN; the buffer layer is selected from AlN, GaN, InN, or any alloys thereof.

10. A complementary logic circuit comprising the device of claim 1.

11. A method of fabricating the device of claim 1, comprising:
providing a structure comprising at least a substrate, a buffer layer, a lower wide-bandgap semiconductor layer, a barrier layer, and an upper wide-bandgap semiconductor layer;
removing partially the upper wide-bandgap semiconductor channel layer to expose partially the barrier layer, leaving an active region of the upper wide-bandgap semiconductor channel layer on the barrier layer for subsequently engaging a gate structure;
providing a pair of identical ohmic contacts on two opposing sides of a region of the barrier layer from where the upper wide-bandgap semiconductor channel is removed;
providing a pair of unidentical ohmic contacts on two opposing sides of the active region of the upper wide-bandgap semiconductor channel layer from where the gate structure is to be engaged;
providing a recess at the active region of the upper wide-bandgap semiconductor channel layer for engaging the gate structure;
providing a charge trapping layer on top of a surface of the recess of the upper wide-bandgap semiconductor layer;
providing an insulating layer over the ohmic contacts, the charge trapping layer and other regions on the upper wide-bandgap semiconductor channel layer and barrier layer than those provided with the ohmic contacts;
providing the gate electrode over the recess of the upper wide-bandgap semiconductor channel layer to cover at least the gate foot region at where the insulating layer is provided over the charge trapping layer in the recess;
selectively removing the insulating layer from those covering the horizontal surface of the ohmic contacts and partially the vertical surface thereof such that the upper wide-bandgap semiconductor channel layer remains insulated by the insulating layer while the contact windows of the corresponding ohmic contacts are opened; and
depositing pad metal on the gate electrodes and ohmic contacts to form pad thereon.

12. The method of claim 11, wherein the charge trapping layer is provided through plasma treatment comprising oxygen plasma treatment to the upper wide-bandgap semiconductor channel layer, or through epitaxial growth with chemical vapor deposition, molecular beam epitaxy, sputtering, atomic layer deposition, or evaporation, or alike.

13. A method of fabricating a monolithically integrated enhancement mode (E-mode) n-channel field effect transistors (n-FETs) and p-channel field effect transistors (p-FETs) on a single substrate for wide-bandgap semiconductor-based complementary logic (CL) gate in a single process run, comprising:
providing a substrate layer with a buffer layer arranged over the substrate layer,
a lower wide-bandgap semiconductor channel layer arranged over the buffer layer,
a barrier layer arranged over the lower wide-bandgap semiconductor channel layer, and
an upper wide-bandgap semiconductor channel layer arranged over the barrier layer;
providing a hard mask over the wide-bandgap semiconductor channel layer with the second doping type for masking during a subsequent patterning;
selectively removing unmasked upper wide-bandgap semiconductor layer from a gate region of the n-FETs and a region outside the p-FETs;
removing hard mask from where the upper wide-bandgap semiconductor channel is selectively removed, followed by depositing the surface passivation layer on p-FETs and n-FETs regions;
providing corresponding ohmic contacts on the n-FETs and p-FETs by opening contact windows in corresponding regions on the surface passivation layer, respectively;
removing the surface passivation layer over the gate region of the p-FETs, followed by recessing the upper wide-bandgap semiconductor channel layer to form a recessed p-FET gate region;
subjecting the recessed p-FET gate region to surface treatment, followed by depositing a dielectric layer onto both the n-FETs and p-FETs;
isolating the n-FETs and p-FETs by a multi-energy level ion implantation;
selectively removing the dielectric layer from the corresponding ohmic contacts and gate region of the n-FETs;
providing gate electrodes over the corresponding gate region of the n-FETs and p-FETs, respectively; and
depositing pad metal on the gate electrodes and ohmic contacts to form pad thereon.

14. The method of claim 13, wherein the lower and upper wide-bandgap semiconductor channel layers are made of GaN, SiC, AlN, Ga₂O₃, diamond, or a wide-bandgap semiconductor heterojunction structure selected from a AlGaN/GaN, AlN/AlGaN/GaN, AlGaN/AlN/GaN, AlN/AlGaN/AlN/GaN, or AlN/GaN structure.

15. The method of claim 13, wherein the dielectric layer is made of SiO, AlO, GaO, ZrO, HfO, or HfZrO, or nitride dielectric materials comprising SiN, SiON, AlON, or GaON.

16. The method of claim 13, wherein the surface passivation layer is made of SiO, AlO, GaO, ZrO, HfO, or HfZrO, or nitride dielectric materials comprising SiN, AlN, SiON, AlON, or GaON, or a bilayered or multilayered dielectric materials comprising AlN/SiN, AlN/SiO, AlN/AlO, AlON/AlN/SiN, AlON/AlN/SiO, or AlON/AlN/AlO.

17. The method of claim 13, wherein the surface treatment on the recessed p-GaN gate region is implemented by plasma treatment including, but not limited to, oxygen plasma, hydrogen plasma, and nitrogen plasma, or solvent treatment including, but not limited to, hydrochloric acid, hydrosulfuric acid, hydrofluoric acid, piranha solution, tetramethylammonium hydroxide solution, ammonia solution with or without dilution.

18. The method of claim 13, wherein the corresponding gates of the n-FETs to p-FETs have a gate aspect ratio of 1:10.

19. An integrated gallium nitride-based complementary logic gate prepared according to the method of claim 13.

20. A single-stage or multi-stage logic circuit comprising one or more of the integrated gallium nitride-based complementary logic gates according to claim 19, wherein said single-stage logic circuit comprises inverters, not-or (NOR) gates, not-and (NAND) gates, and transmission gates; the multi-stage logic circuit comprises latch cell and ring oscillator.
